(19) United States
(12) Patent Application Publication
(10) Pub. No.: US 2024/0372362 A1
(43) Pub. Date: Nov. 7, 2024

(54) MODELING PERFORMANCE FOR SOLAR MODULE TRACKERS

(71) Applicant: Nevados Engineering, Inc., Oakland, CA (US)

(72) Inventors: Yezin TAHA, San Francisco, CA (US); Kurt RHEE, San Francisco, CA (US); Jason ALDERMAN, Oakland, CA (US)

(73) Assignee: Nevados Engineering, Inc., Oakland, CA (US)

(21) Appl. No.: 18/651,251

(22) Filed: Apr. 30, 2024

Related U.S. Application Data
(60) Provisional application No. 63/463,224, filed on May 1, 2023.

(51) Int. Cl. H02J 3/00; G06F 30/20; H02J 3/38

(52) U.S. Cl. CPC H02J 3/004; G06F 30/20; H02J 3/38; H02J 2300/24

(57) ABSTRACT

Modeling performance of solar trackers at a solar site in order to accurately predict performance while subject to the limitations of available processing resources. Certain aspects of this invention include transposition modeling each individual bay of a solar site with terrain-adaptive backtracking schedules that prevent interrow shading. Further aspects include simplifying the bay composition of the solar site and/or the backtracking schedule, such as by averaging or otherwise choosing a representative angle amongst a plurality of angles, in order to simplify the modeling performance while still obtaining an accurate result.

### CROSS REFERENCE TO RELATED APPLICATIONS

This application claims priority to U.S. Provisional Application 63/463,224 titled “MODELING PERFORMANCE FOR SOLAR MODULE TRACKERS” filed on May 1, 2023, which is incorporated by reference herein in its entirety.

### FIELD OF THE INVENTION

The invention relates generally to solar trackers, specifically modeling performance for solar trackers.

### BACKGROUND

Two types of mounting systems are widely used for mounting solar panels. Fixed tilt mounting structures support solar panels in a fixed position. The efficiency with which panels supported in this manner generate electricity can vary significantly during the course of a day, as the sun moves across the sky and illuminates the fixed panels more or less effectively. However, fixed tilt solar panel mounting structures may be mechanically simple and inexpensive, and in ground-mounted installations may be arranged relatively easily on sloped and/or uneven terrain.

Single axis tracker solar panel mounting structures allow rotation of the panels about an axis to partially track the motion of the sun across the sky. For example, a single axis tracker may be arranged with its rotation axis oriented generally North-South, so that rotation of the panels around the axis can track the East-West component of the sun's daily motion. Alternatively, a single axis tracker may be arranged with its rotation axis oriented generally East-West, so that rotation of the panels around the axis can track the North-South component of the sun's daily (and seasonal) motion. Solar panels supported by single axis trackers can generate significantly more power than comparable panels arranged in a fixed position.

The amount of grading required to install a single axis tracking system may decrease the economic efficiency of those single axis trackers. Deficiencies in the tracker rotation strategy, which dictate how the trackers follow the sun, may also decrease the efficiency.

Certain state-of-the-art single axis trackers are designed specifically to reduce or eliminate the grading requirement by employing specialized bearings that can handle post-to-post net angle changes. A solar array site may have multiple trackers, and each tracker may have multiple bays of solar modules. A bay is a contiguous series of solar modules bounded by posts, and each bay may have its own distinct normal vector. The variability of the normal vectors from bay to bay comes from reducing the grading requirement, allowing the solar modules to be installed on non-flat, undulating terrain. However, this also makes the trackers more vulnerable to shadowing resulting from cross axis and intra-tracker axis slopes.

A basic tracking algorithm used by many trackers is called true-tracking. Its aim is relatively simple: to minimize the incidence angle between the normal vector of the solar panel and the incoming beam from the sun. Solar panels are lain flat at solar noon and are tilted in early and later in the day to face the sun when it is at low elevation. The steep tilt during certain times may cause shading between trackers, resulting in potentially significant power loss from a pure true-tracking approach. This shading by trackers on other trackers is often referred to as row-to-row shading, since a tracker can be thought of as a row of solar modules, even when there are angle changes within the tracker.

As a result, basic backtracking algorithms were developed to improve on true-tracking. During those times when shading is most likely to be caused in the morning and late evening hours, the angles of the solar modules are reduced (e.g., the modules are made flatter) to prevent shading. These basic backtracking algorithms assume that the trackers are on an entirely flat plane.

More advanced backtracking algorithms, which can be termed cross-slope aware backtracking, take into account that two trackers may each have different planes (higher or lower) in the east or west. The angle between these two planes, called the cross-axis slope, extends infinitely such that all trackers that fall within the scope of each algorithm run will inherit the same cross axis slope. Cross-slope aware backtracking can fail to prevent shading in three ways. First, if the cross-axis slope is not constant throughout the entire site, and there are any slope changes, the algorithm may fail to take those changes into account and prevent row-to-row shading. Second, if the trackers have differing slopes along the tracker axis direction, then the two planes of the trackers are not parallel with one another, which could cause also cause issues. Lastly, even if the slopes in the tracker axis direction are taken into account, such algorithms may only consider the slope tracker as a whole, when there can be changes in slope between the posts within each tracker. These changes can also cause a failure to prevent shading.

Even more advanced backtracking algorithm are needed to prevent interrow shading, which must be more terrain-adaptive than the ones listed above. However, the progression of ever more advanced backtracking algorithms may outpace the capability of performance modeling programs to model these backtracking algorithms. Accurately modeling performance of a solar site once it is installed or before it is installed is important to the understand the economics of a solar site, since knowing the energy generated allows one to determine the likely return on investment at a site. If the modeled performance may overestimate the energy produced, it might cause one to make a bad investment and install in a poor site that cost more to install and maintain than the energy obtained is worth. If the modeled performance underestimates the energy produced, it might cause one to overlook a good site to install over another site that actually performs worse.

Current performance modeling software cannot yet directly model the performance benefit of operating a horizontal single-axis tracking system on variable terrain if that system employs a terrain-adaptive backtracking strategy. This is because no commercial performance modeling software can currently calculate which rotation angle each individual tracker should be set to in order to avoid interrow shadowing. Current complete methods for modeling terrain-following systems, such as modeling the system as if it were built on flat terrain, will over-estimate the performance of the system. On the other hand, modeling a terrain-following system on a variable surface with a standard ground coverage ratio based backtracking algorithm will under-estimate the system production due to terrain shading losses. Systems which utilize a terrain-adaptive backtracking strategy will produce some amount of energy between these two extremes, but understanding exactly how much energy without time-consuming pre-processing, postprocessing or approximation has not yet been solved in the industry.

Horizontal single-axis trackers have generally been modeled in performance modeling software as flat arrays of repeating tracker rows, with each row indistinguishable from the row next to it. This simplification results in under-performance of the trackers due to shade loss not captured by this method of modeling. There has been an increasing effort in the solar industry to construct sites on ground that is not flat, and horizontal single-axis tracking hardware is evolving to meet the task. As this new type of tracking hardware evolves, so must the performance modeling methods and tools used to obtain accurate models of past and future plant performance.

### SUMMARY

Embodiments of this invention include modeling performance of solar trackers at a solar site in order to accurately predict performance while subject to the limitations of available processing resources. Certain aspects of this invention include transposition modeling each individual bay of a solar site with terrain-adaptive backtracking schedules that prevent interrow shading. Further aspects include simplifying the bay composition of the solar site and/or the backtracking schedule, such as by averaging or otherwise choosing a representative angle amongst a plurality of angles, in order to simplify the modeling performance while still obtaining an accurate result.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### BRIEF DESCRIPTION OF THE DRAWINGS

FIG. 1 depicts an example of an all-terrain solar tracker arranged on sloped and rolling terrain with angle changes along its length to follow the natural terrain.

FIG. 2 depicts a perspective view of solar panel trackers on sloped and rolling terrain.

FIG. 3 depicts a cross-sectional view (looking down an East-West axis) of solar panel trackers on sloped and rolling terrain.

FIG. 4 depicts a cross-sectional view (looking down a North-South axis) of solar panel trackers on sloped and rolling terrain.

FIG. 5 depicts a flow diagram illustrating a raycasting process to determine a backtracking schedule in a solar site array.

FIG. 6 depicts raycasting done on two bays where an intersection test is performed on one of the two bays.

FIG. 7 depicts a flow diagram illustrating a modeling process to determine energy production in a solar site array.

FIG. 8 depicts a flow diagram illustrating a modeling process to determine energy production in a solar site array.

FIG. 9 depicts a graph including rotation angles of an optimized terrain-adaptive backtracking schedule for trackers, and a lowest rotation angle at each time step among the trackers.

FIG. 10 depicts a graph including rotation angles an optimized terrain-adaptive backtracking schedule for trackers, and an average rotation angle at each time step among the trackers.

FIG. 11 depicts a flow diagram illustrating a modeling process utilizing retro-transposition to determine energy production in a solar site array.

FIG. 12 depicts a flow diagram illustrating a modeling process to determine energy production in a solar site array.

FIG. 13 shows a block diagram of a computer system in communication with a solar panel array.

FIG. 14 shows a block diagram of a solar panel control system in communication with a solar panel array.

FIG. 15 depicts a histogram model of North-South torque tube axis-tilts for bays in a physically installed solar array with terrain-adaptive trackers.

FIG. 16 depicts a histogram model of cross axis-tilt for bays in a physically installed solar array with terrain-adaptive trackers.

FIG. 17 depicts a histogram model of axis-tilt mismatch in a physically installed solar array with terrain-adaptive trackers.

FIGS. 18a-b depicts graphs comparing the rotation angles and the resulting plane of array insolation from a range of ground coverage ratio based backtracking strategies to ray-casting based rotation angles and plane of array insolation.

FIG. 19 depicts a graph comparing plane of array insolation generated by TRACE compared with that generated by retro-transposition and re-transposition generated by PVSyst.

FIG. 20 depicts a 3D model of a physically installed solar array with terrain-adaptive trackers including pile-to-pile bearings and angle changes.

FIG. 21 depicts a 3D model of a solar array of bays with a solar position vector, a normal plane, and an x-y plane.

FIG. 22 depicts a 3D model of a solar array projected on a normal plane.

FIG. 23 depicts a 3D model of a re-projection of the projection shown in FIG. 22, the re-projection on the x-y plane.

FIG. 24 depicts a 3D model of the re-projected projection shown in FIG. 23, with an overlap of the polygons (e.g., at the corner) indicating shading in the solar array.

FIG. 25 depicts a flow diagram illustrating a point-in-polygon process to determine a backtracking schedule of a solar array.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries. The term “vertical” refers to a direction parallel to the force of the earth's gravity. The term “horizontal” refers to a direction perpendicular to “vertical”.

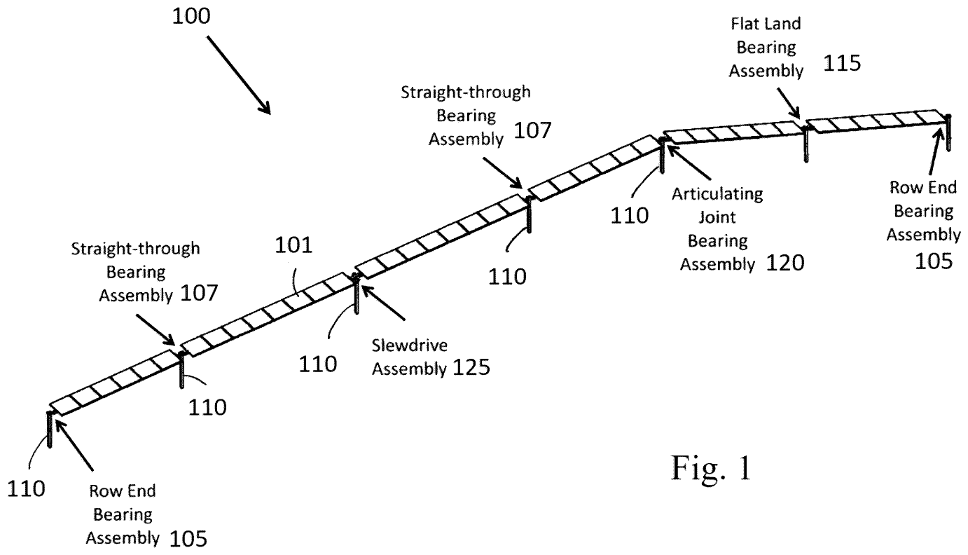

FIG. 1 illustrates an example variable terrain solar tracker, which employs support posts 110, solar panel module supports such as torque tubes extending between the support posts, and solar panel modules 101 supported by the torque tubes (the solar panel modules disposed directly on the torque tubes are hereinafter referred to as “solar panel modules” to distinguish them from the “solar panel” included in the pony module 200, to be further described later). Multiple solar panel modules may be between each of the support posts, and they may all be of a same size as one another. The number of solar panel modules between each of the support posts may be the same along the tracker, or it may vary depending on the terrain and the spacing of specific support posts.

This example variable terrain solar tracker is arranged on uneven terrain and includes two rotation axes: a first rotation axis arranged along a slope, and a second horizontal rotation axis along a flat portion of land above the slope. The angle between the first rotation axis and the second horizontal rotation axis may be, for example, ≥0 degrees, ≥5 degrees, ≥10 degrees, ≥15 degrees, ≥20 degrees, ≥25 degrees, ≥30 degrees, ≥35 degrees, 40 degrees, ≥45 degrees, ≥50 degrees, ≥55 degrees, ≥60 degrees, ≥65 degrees, ≥70 degrees, ≥75 degrees, ≥80 degrees, ≥85 degrees, or up to 90 degrees. These examples refer to the magnitude of the angle between the first rotation axis and the second horizontal axis. The angles may be positive or negative.

Various types of assemblies may be disposed on top of support posts, depending on the terrain and the position of the support post with relation to the rest of the trackers: straight-through bearing assemblies for sloping planar surfaces, flat land bearing assembly for flat land, row end bearing assembly for an end of a the tracker, articulating joint bearing assembly for changing terrain angles, and drive device assembly at an end of the tracker or an intermediate position along the tracker in order to drive rotation of the tracker.

For example, opposite ends of the tracker are rotationally supported by row end bearing assemblies 105 on support posts 110. The portion of the tracker arranged on the slope is supported by straight-through bearing assemblies 107, which include thrust bearings that isolate and transmit portions of the slope load to corresponding support posts 110. The portion of the tracker arranged on flat land, above the slope, is rotationally supported by a flat land bearing assembly 115 which may be a conventional pass-through bearing assembly lacking thrust bearings as described above. The drive device may be a slew drive that drives rotation of the solar panel modules 101 and the solar panel 210 about the first and second rotation axes to track the sun. The solar panel modules 101 may be supported on torque tubes that are parallel with and optionally displaced (e.g., displaced downward) from the rotation axis of the slew drives. The torque tubes may also be aligned with rather than displaced from the rotation axis of the slew drives. Articulating joint bearing assembly 120 links the two non-collinear rotation axes and transmits torque between them. Example configurations for bearing assemblies 105, 107 and 120 are described in more detail below.

Other variations of the variable terrain solar tracker 100 may include other combinations of bearing assemblies 105, 107, 115, and 120 arranged to accommodate one, two, or more linked rotational axes arranged along terrain exhibiting one or more sloped portions and optionally one or more horizontal (flat) portions. Two or more such trackers may be arranged, for example next to each other in rows, to efficiently fill a parcel of sloped and/or uneven terrain with electricity-generating single axis tracking solar panels.

Referring again to FIG. 1, as noted above articulating joint bearing assembly 120 accommodates a change in direction of the rotational axis along the tracker. As used herein, “articulating joint” refers to a joint that can receive torque on one axis of rotation and transmit the torque to a second axis of rotation that has a coincident point with the first axis of rotation. This joint can be inserted between two spinning rods that are transmitting torque to allow the second spinning rod to bend away from the first spinning rod without requiring the first or second spinning rod to flex along its length. One joint of this type, which may be used in articulating joint bearing assemblies as described herein, is called a Hooke Joint and is characterized by having a forked yoke that attaches to the first spinning rod, a forked yoke attached to the second spinning rod, and a four-pointed cross between them that allows torque to be transmitted from the yoke ears from the first shaft into the yoke ears of the second shaft.

A solar panel array control system may be provided, which may control operation of one or more solar panels in the solar array. Operation of the one or more solar panels may include positioning of the one or more solar panels. For example, the solar panel array control system may control an orientation of one or more solar panels. The control system may send signals to a solar panel supporting structure, which may affect the position of the one or more solar panels. The articulating joint may be capable of allowing a position of a solar panel to be controlled from the control system.

Certain state-of-the-art single axis trackers are designed to be able to handle non-flat terrain by building with a non-continuous torque-tube which is held by specialized bearings. These specialized bearings can handle pile to pile net angle changes of up to 15 degrees. In these trackers, each section of torque-tube to which photovoltaic modules are connected is called a bay, and each bay has its own unique tilt angle in the axis of the torque-tube.

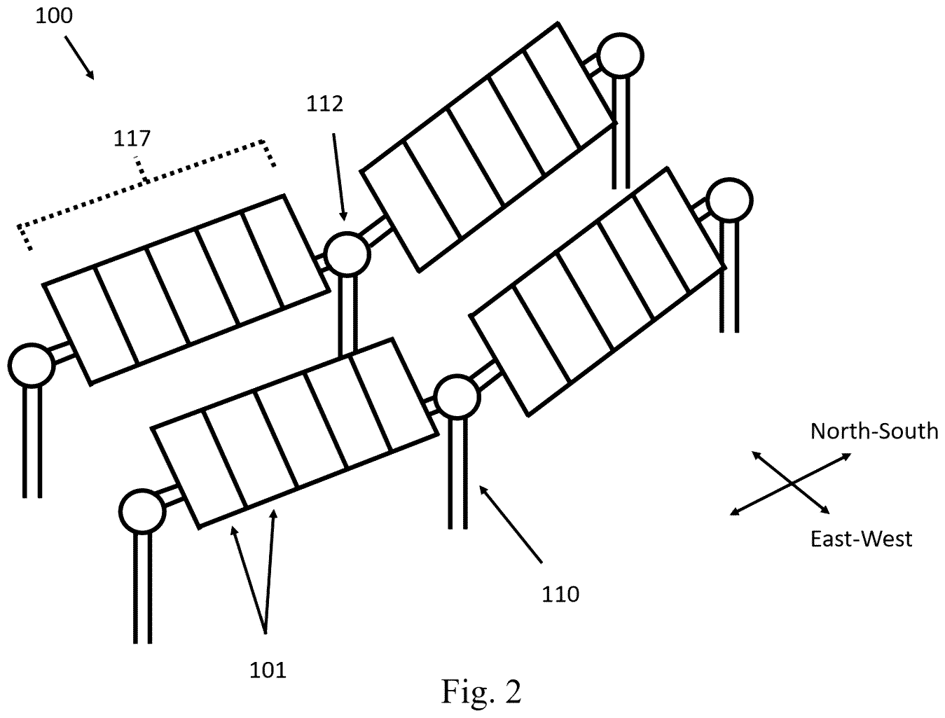

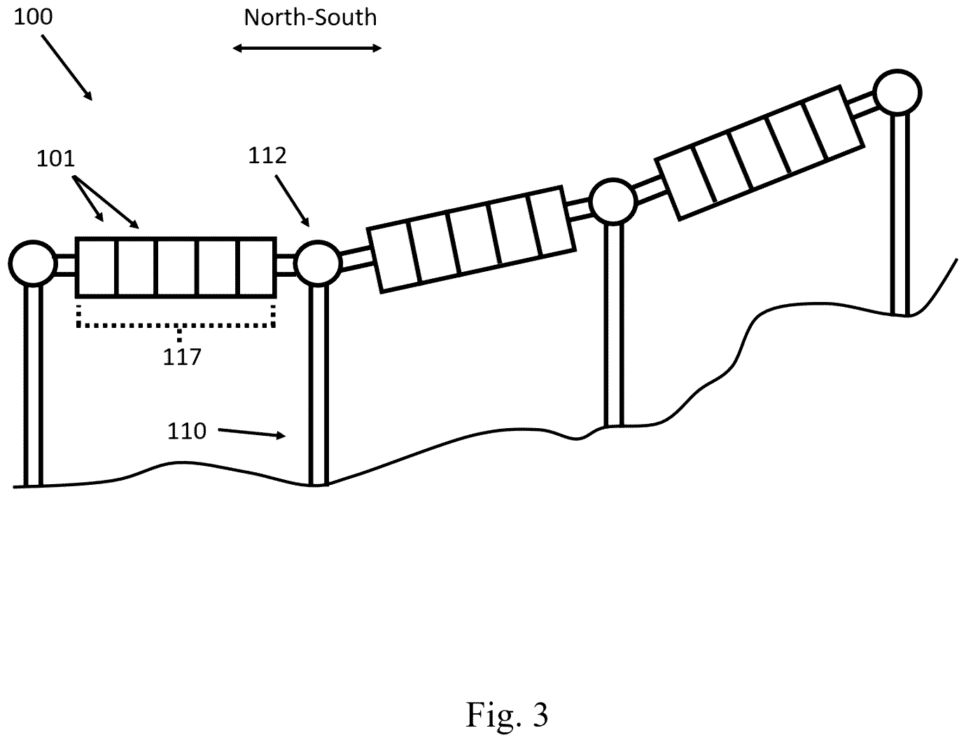

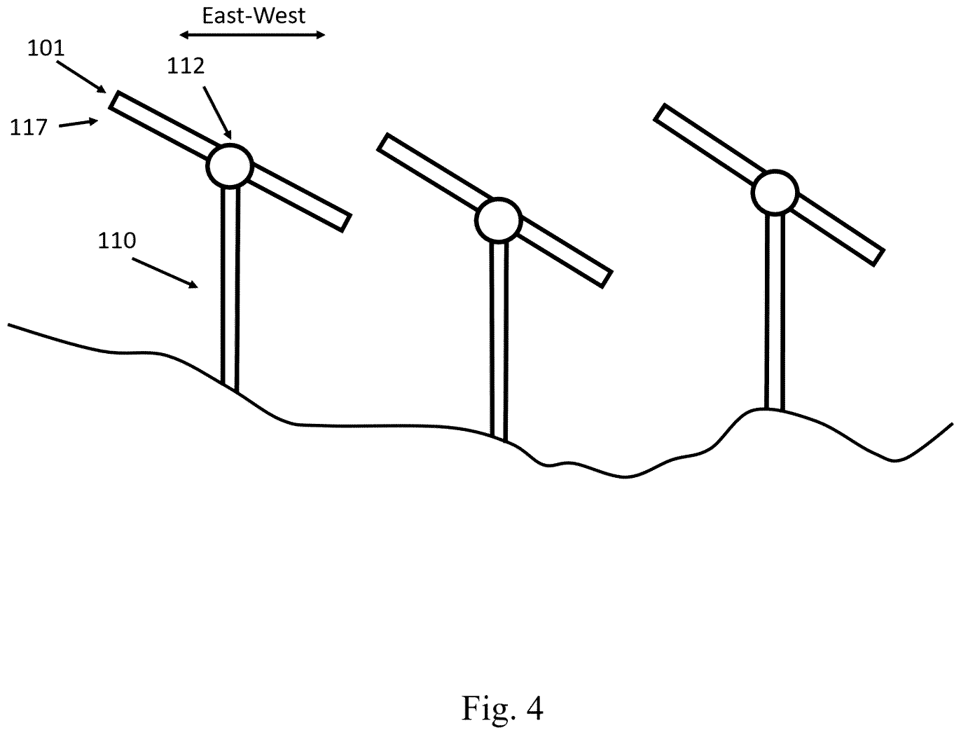

FIGS. 2-4 illustrates an array of solar panels of a solar site, including single axis trackers and bays. FIG. 2 depicts two trackers in the solar site array directly adjacent to each other, each running along or approximately along the north-south direction with solar modules extending lengthwise in or approximately in the east-west direction. An angle change is depicted in both trackers at the bearing assembly 112. Bearing assemblies 112 disposed on a support 110 could be any of the bearing assemblies described above, such as an articulating bearing assembly. A bay 117 includes a series of one or more solar modules disposed directly adjacent to each other, such as eight or less modules, such as ten or less modules, such as more than ten modules. The bay 117 may be bounded by bearing assemblies 112 and disposed on a single torque tube. A single bay 117 may have solar modules 101 that have parallel normal vectors and also lie on a same plane as each other, which holds true even as the torque tube rotates the solar modules. FIG. 3 depicts a cross section of a solar site array looking along the east-west axis. A single tracker with three bays 117 is depicted from the solar site array. FIG. 4 depicts a cross section of a solar site array looking along the north-south axis. Three trackers of the solar site array are depicted side by side on the sloped landscape. The solar modules 101 in the bays 117 are tilted away from the horizontal. As evident from the figure, it is possible for directly adjacent trackers (i.e., neighboring trackers) along the east-west axis to shade each other with their bays 117, depending on the direction of the sun and their cross-axis slopes. The trackers depicted within each of the above figures may all be attached to a separate row controller, with all of the row controllers being attached to a same central controller.

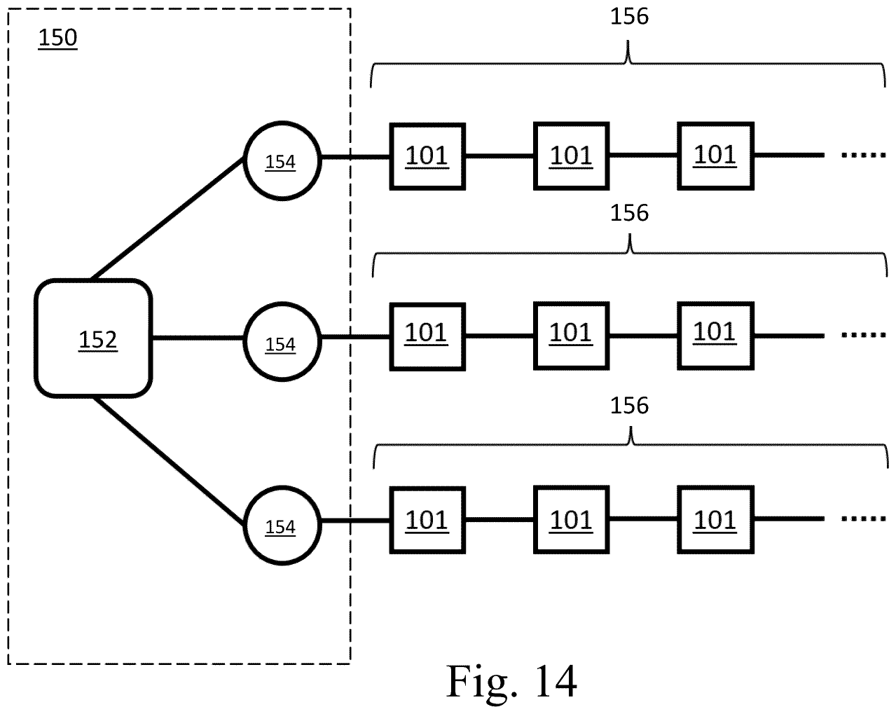

FIG. 14 shows an example of a solar panel array control system 150 coupled to a solar panel array. The solar panel array control system 150 may communicate with the solar panel array. The solar panel array control system 150 and/or elements of the solar panel array control system 150 (such as the central controller 152 and/or group control systems 154) may include, be included in, or consist of the computer system 320 or elements of the computer system 320 described above.

The solar panel array may include one or more solar panel groups 156 each including one or more solar panel modules 101. The groups 156 may include one or more solar panels connected in series, in parallel, or any combination thereof. The solar panel groups may include rows of solar panels, and may be trackers 100 as described above. Any description herein of rows of solar panels may apply to any other type of arrangement or grouping of solar panels.

Optionally, each group of solar panels may each have (e.g., be coupled to and in communication with) a group control system 154. Each group control system 154 may control operation their respective solar panel group 156. The group control systems 154 may be referred to as row controllers when controlling rows of solar panels. Any number of solar panel groups and/or group control systems may be provided. Each group may comprise any number of solar panels. Each group may have the same number of solar panels or differing numbers of solar panels. A central controller 152 may optionally be provided that may control the group control systems.

The solar panel array control system 150 may comprise the central controller 152 and, optionally, one or more group control systems 154. In some instances, one-way communication may be provided from the central controller to the one or more group control systems. The central controller may send instructions to the one or more group control systems, which may in turn control operation of the corresponding solar panel groups. In some instances, two-way communication may be provided between the central controller and the one or more group control systems. For instance, the group control systems may be group controllers that may send data to the central controller. The central controller may send instructions to the group controllers, for example in response to, or based on, the data received from the group controllers. The data from the one or more group controllers may optionally include data from one or more solar panels, or various types of sensors physically included as part of the solar panel group (e.g., on a torque tube, foundation, bearing assembly, or other part of the tracker), physically remote from the solar panel group, and/or otherwise physically or electrically coupled to the solar panel group.

The solar panel array control system may direct and affect operation of the solar panels, which may include positioning of the solar panels. The control system may affect an orientation of the solar panel. The control system may control amount of rotation, rate of rotation, and/or acceleration of rotation of one or more solar panels. The control system may affect a spatial disposition of the solar panel. The control system may control an amount of translation, speed of translation, and/or acceleration of translation of one or more solar panels. The control system may affect operation of one or more driving mechanisms for a solar panel array, for example by sending signals to the slew drive coupled to one or each of the solar panel groups, which may then control orientation of the solar panels. The solar panels may be positioned in response to one or more factors, as previously described herein. The solar panel array control system may affect other operations of the solar panels, such as turning the solar panels on or off, operational parameters of converting the solar energy to electrical energy, diagnostics, error detection, calibration, or any other type of operations of the solar panels.

In one example, a method of optimizing power generation throughout a field of trackers may be provided. Operational data for each grouping (e.g., each row) of solar panels may be provided. Any description herein of a row may apply to any grouping. The method may include collecting row-level operational data in aggregate, or piecemeal, to determine the operational characteristics of one or more rows of trackers. Power generation data of each row may be measured to determine if shading is occurring from one row to the next. The method may include analyzing total field power generation to determine if shading specific rows, while further optimizing or adjusting the tilt of other rows for generating power, will increase overall field power generation.

Row-level tests may be performed to determine the impact of shading of one or more rows on the one or more neighboring rows with regard to power generation of the neighboring rows. Row-level tests may be performed on one or more rows to determine if an optimum orientation assumption yields optimum or increased power generation. Tracking schedules may be updated to optimize or increase power generation throughout a tracker field or for each individual row. Row-level power generation may be monitored and compared with weather station reports to determine if sun-tracking operations or non-sun-tracking operations will yield greater power generation. Based on the comparison, an operation may be selected to yield the greater power generation.

It is useful to model the performance of an array at a solar site, whether or not the array has been installed yet. Determining this power may include simulating, via a 3D model, optical, electrical, and/or thermal performance of the array. Modeling arrays at different sites can allow one to choose the best install site which will provide the best energy performance in relation to the install cost, that is, to choose between two or more install sites based on whichever site generates more energy and/or generates energy more efficiently in relation to install cost. After the performance modeling is done according to embodiments of the invention, the solar array may be physically installed at the chosen site.

However, for state-of-the-art single axis trackers as those described above, most current performance modeling software programs disregard the change in angle that can occur at each bearing for terrain-following trackers, considering each bay to have the same angle as the one before and after it. Most software programs also disregard the unique backtracking algorithms that are required when operating terrain-following trackers to avoid shading electrical losses. A few standout software programs allow custom tracker angles to be used, both in terms of torque-tube axis angle in the north to south direction, and in terms of tracker rotation angle. These software programs and others like them, coupled with customized terrain adapted backtracking schedules, can be used to accurately model the performance of terrain-adaptive backtracking strategies. This can be done even before the plant is constructed.

Certain tools and methods have been developed in order to more precisely model the amount of energy generated by a solar tracking system, and prevent over-estimation and under-estimation from more conventional approaches. For example, these tools and methods may take the form of software program(s) which generates terrain-adaptive tracker rotation schedules that may be used to accurately model the performance of terrain-following trackers which employ advanced backtracking strategies. For example, the tracker rotation schedules may be imported into performance modeling software. A number of different approaches have been developed to approximate the results in performance modeling software programs which do not allow the user to input custom tracker rotation angles.

For those completing performance models using software which cannot accept custom, variable tracker axis-tilt angles and custom, variable tracker rotation angles, embodiments of the invention generate simplified models which can be used to approximate the results of advanced performance modeling tools. Independent of which modeling tool is being employed, a more accurate pre-construction estimate of site energy production may be desired by photovoltaic project developers and asset owners in order to make better informed investment decisions.

In order to properly model a terrain-following single-axis tracker system, a few things must occur which differ from the standard modeling steps taken for a flat system. If the system is backtracking, then a time-series of rotation angles should be calculated for each individual tracker which avoids row-to-row shading at all time-steps. A transposition model for each bay with its unique normal vector pointing outwards from the module surface should be calculated for every time-step.

### Reference Models

Modeling as Flat & GCR Based Backtracking: The default in most performance modeling software systems is to model the entire solar site as being installed on flat ground. A solar site constructed on variable terrain may be modeled with a performance modeling program using a standard Ground Coverage Ratio (GCR) backtracking algorithm. Because this backtracking algorithm does not take into account the effects of the terrain, modeling or operating a variable terrain site with a flat terrain backtracking algorithm will cause shading electrical effect losses. As a result these models are mostly used as references and comparative examples.

Average Tracker Axis-Tilt: Some performance modeling software may not allow entering custom tracker rotation schedules. If tracker-axis-tilt can be adjusted as a variable, then an approximation can be made which only averages all of the torque tube axis-tilts across the entire site, without any other modifications. The system can then be modeled as a single repeating tracker array sharing a common tracker-axis-tilt.

Commissioned Backtracking: One possibility of mitigating the shading effects of the terrain is to set the site backtracking algorithm's ground coverage ratio (GCR) to a number that is more closely spaced than the actual tracker spacing. Say for example the trackers are spaced at a ground coverage ratio of 0.33, one could set an artificial ground coverage ratio greater than 0.33 in order to reduce the amount of inter-row shading that occurs. This method allows the site to avoid inter-row shading while also keeping all trackers at the same rotation angle as the site plane of array irradiance sensors. In order to determine which artificial ground coverage ratio is appropriate, an array of rotation schedules is generated using the standard ground coverage ratio based method. The array begins at the as-built site ground coverage ratio and iteratively increments upwards by 1 percent until estimated plane of array insolation drops below a set threshold, indicating that shading is occurring or in danger of occurring. Because standard backtracking algorithms cannot take into account eastern or western aspects or variable terrain, some shading may still occur with this method. In the over-simplified model, the contribution of a shaded bay to total plant transposition is equal to only the diffuse portion of the incident irradiance. This model is intended to very roughly mimic the effects of electrical mismatch along the string.

### Bespoke Transposition Modeling

According to embodiments of this invention, the most rigorous method for modeling transposition is to individually model the transposition for every bay in a given solar site, e.g., after a backtracking schedule of rotation angles has been obtained from the raycasting method (described further below). For example, a 100 MW site built with trackers of non-continuous torque tubes (e.g., with bearings at support posts supporting and spacing apart incoming and outgoing torque tubes) this would mean approximately 36,000 bays. For a typical meteorological year time series at a 1 hour time-step this would mean 315,360,000 calculations. A 500 MW site at a 1 minute time step would require approximately 94.6 billion calculations. Depending on the computation power available, this method may be used to obtain the most accurate modeling of how much power can be obtained from a site. For example, a backtracking schedule may be generated via the raycasting method for a solar site on sloped ground, where the backtracking schedule avoids interrow shading between trackers. Then, the backtracking schedule is used to determine the power generated. For example, the backtracking schedule may be input into certain software tools that fully or substantially fully accept these schedules as input (e.g. PlantPredict™ by Terabase® or SolarFarmer® by DNV®). In addition to the backtracking schedule, additional inputs may be required by the modeling program, such as Global Horizontal Irradiation (GHI), Direct Normal Irradiation (DNI), and/or Diffuse Horizontal Irradiation (DHI).

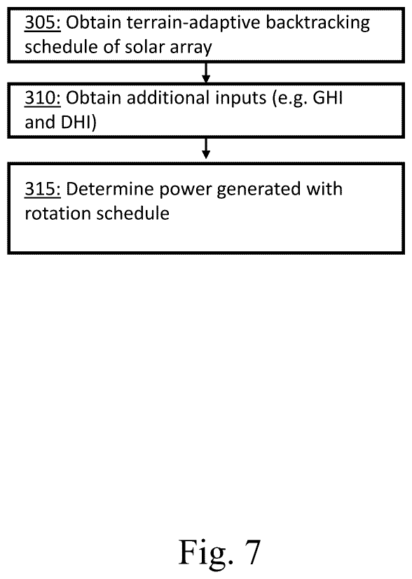

FIG. 7 illustrates this process. At 305, a rotation schedule may be obtained that is a terrain-adaptive backtracking schedule, meaning it prevents interrow shading despite the varying axial and/or cross-axial slopes across the site. This schedule may be obtained by a raycasting method, described further below. At 310, other inputs required by the modeling program, such as GHI and DHI, may be obtained. These inputs may be obtained in via a database based on the geographical location of the site and/or measured by satellite or sensors at the location. Some programs use DNI instead of or in addition to GHJ. In this specification, unless otherwise stated, anytime GHI is mentioned as an input it is understood that DNI may be used in its place or in addition to GHJ. At 315, the power of the solar site is determined based on the schedule and the inputs. Determining this power may include simulating, via a 3D model, optical, electrical, and/or thermal performance of the array with the obtained backtracking schedule. Within this simulation, the global plane of array (GPOA, which is a plane of array of all the solar panels at a site, that is to say the irradiance received by potentially angled solar panels) may be determined and used to ultimately determine the total power of the solar site.

Sometimes, when the site has too many trackers/bays and computational resources or the modeling program itself are limited, a method with more simplification may be preferable, as presented below.

Limit Backtracking/Rotation Schedule and/or Axis-Tilt

While certain performance modeling programs allow as input a custom terrain-adaptive backtracking schedule and/or a GPOA, other programs do not. For example, a program may accept custom angles for trackers, but require all trackers to use the same rotation angles and/or axis tilt. In these cases, a simplification still needs to obtain reasonably precise results for a terrain-adaptive backtracking even if the same rotation angle and/or axis tilt is used.

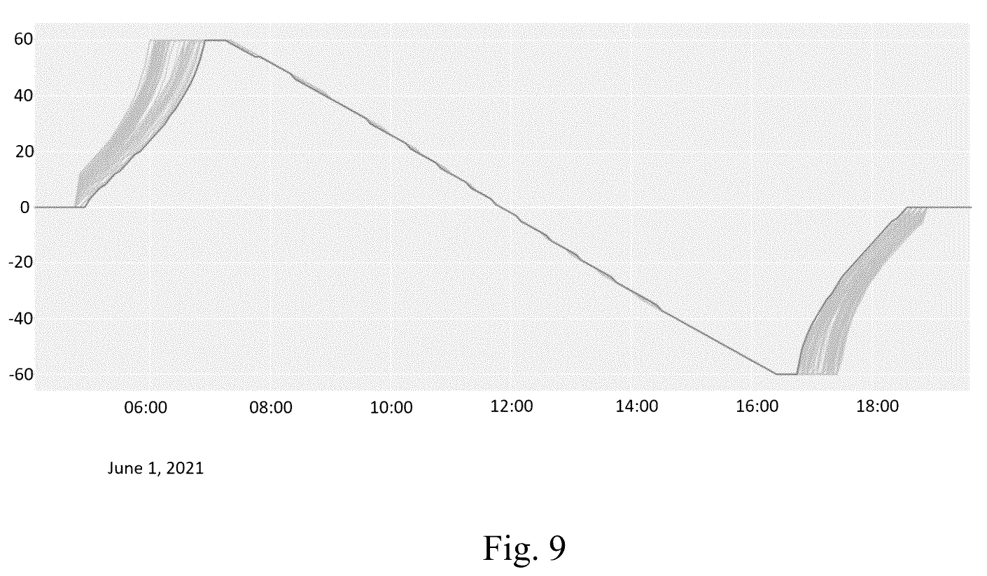

Embodiments of the invention include a method called limit backtracking/rotation schedule, or limit raycasting. Limit backtracking schedule may begin by obtaining a schedule of backtracked angles, such as using the raycasting method to obtain a terrain-adaptive backtracking schedule which tracks the sun and does not cause interrow shading in a solar site installed on sloped land. During at least some times in the day, particularly the early or late times, the backtracked angles of specific trackers may differ from each other. FIG. 9 shows backtracking angles (e.g., obtained by raycasting) for a solar site with a number of trackers, and their individual backtracking angles corresponding to individual time steps which make up a terrain-adaptive backtracking/rotation schedule. The x-axis shows the time of day and the y-axis shows the rotation angle of the tracker. The lighter lines represent the individual rotation angles of different trackers, which differ from each other most dramatically at the early and late parts of the day. As can be seen, the backtracking angles at the early and late parts of the day differ widely between different trackers, and are identical or close to each other through and around noon. The many rotation angles at certain parts of the day may need to be simplified for some performance modeling programs, which do not have the capacity to model so many individually controlled trackers.

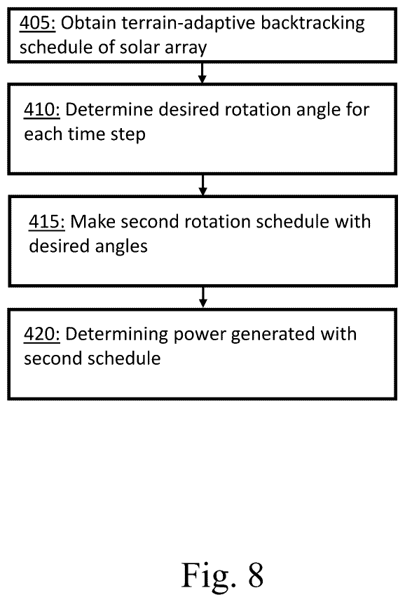

FIG. 8 shows embodiments of the invention expressed in a broad process of simplifying modeling. At 405, a first rotation schedule may be obtained including rotation angles for each tracker installed at a solar site at each time step. The first rotation schedule may be obtained by the raycasting method described above. This first rotation schedule, when used by the trackers at the relevant solar site, may provide a better performance in terms of energy generation than the second rotation schedule, discussed below, but may be too difficult or impossible to model depending on the performance modeling program used.

At 410, a desired rotation angle is determined for each time step. The desired rotation angle may be the lowest rotation angle in the first rotation schedule, considered at every time step. In FIG. 9, the darker line represents the lowest rotation angle for any given time-step (lowest referring to lowest absolute magnitude of the angle in degrees). There may only be one desired rotation angle every time step, in contrast to the rotation angles of all the trackers in the first rotation schedule.

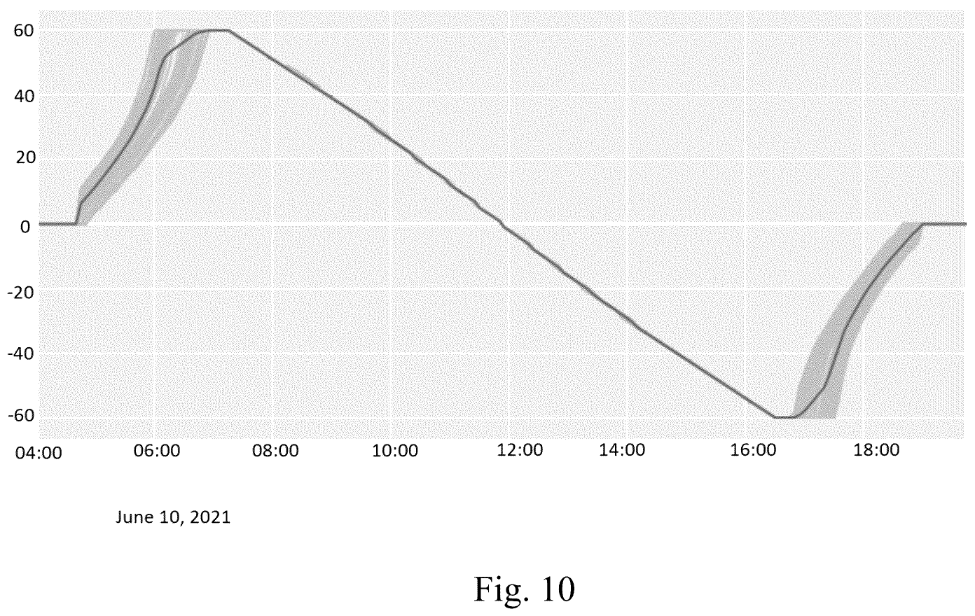

At 415, a second rotation schedule may be made with the desired rotation angle. For example, this lowest rotation angle at every time step is used to simplify modeling. All the trackers in the site may be set to this lowest rotation angle (i.e., the most backtracked angle) for every time-step of the second rotation schedule. This ensures that all trackers are at the same rotation angle, which is useful to simplify modeling, but no shading will occur, which is useful for accuracy of the modeling. For example, if a site has three trackers with calculated optimal rotation angles of 10, 12 and 15 degrees at a time-step, and the site is set to limit backtracking schedule mode, then all three trackers would be set to 10 degrees. Alternatively, the desired rotation angle may be an average rotation angle of all the rotation angles at the time step (of the first rotation schedule). FIG. 10 shows this, as it is similar to FIG. 9 except that the darkest line represents the average rotation angle rather than the lowest rotation angle. There may be only one average rotation angle for every time step.

At 420, using this simplified second rotation schedule, the power of the solar panels at the solar site may be modelled in a manageable way. For example, the performance modeling program may model the entire solar site as array of identical trackers which all rotate at the lowest rotation angle, or the calculated average angle, depending on which is desired. In this way, it is possible to obtain a reasonably accurate result of a terrain-adaptive backtracking solar site even in performance modeling programs with severe modeling restrictions, such as forcing a single angle on all trackers in the site.

Limit backtracking schedule can be used to model the terrain-adaptive backtracking strategies of ganged trackers. A solar site may be broken up into groups of ganged trackers. Sets of ganged trackers are each set to a separate limit backtracking schedule group. Each of these groups would track independently of one another based off of their own limit backtracking schedule schedules. In other words, each of these ganged trackers would be set to their own respective lowest rotation angle at every time-step, so that different ganged trackers may have different lowest rotation angles at the same time-step. This allows more granularity while retaining some of the simplification that makes this limit backtracking schedule method efficient.

Additionally or alternatively to the simplification of the rotation angles, tilt angle equal to the calculated average of torque-tube axis angles of all the trackers may be taken. This average tilt angle becomes the inputted tilt angle of for a performance modeling program which forces modeling the entire solar site as identical trackers with the same tilt angle. Alternatively, the axis-tilt angle may be left as flat for all of the identical trackers.

### Retro-Transposition

While many performance modeling programs may use global horizontal irradiation (GHI) and diffuse horizontal irradiation (DHI) as input, some modeling programs will additionally or alternatively allow GPOA as an input.

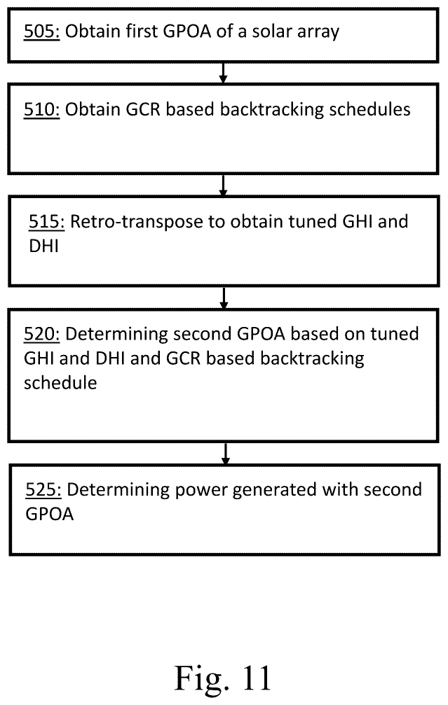

In certain instances GPOA of a plant or site is calculated or measured externally, for example if there are sensors in the field of a physically installed solar site measuring GPOA of the site. When the GPOA is imported into performance modeling programs, some of these programs will retro-transpose GPOA into GHI and DHI. This is because those programs—e.g., PVSyst®—will always start with GHI and DHI. They will then re-transpose the retro-transposed GHI and DHI into a potentially new GPOA, which is the GPOA that they actually use in the simulation model to obtain the energy of the site. However, the results of this retro-transpose, re-transpose process are highly dependent on the underlying transposition models as well as the rotation angles assumed. In PVSyst, the Hay model is used for retro-transposition, and the backtracking schedule dictated by PVSyst may be a standard gcr-based schedule rather than a desired terrain-adaptive backtracking strategy (such as that obtained by raycasting). The lack of choice and use of potentially undesirable models or backtracking schedules may result in an inaccurate result in performance modeling. More precise results for the operations of a terrain-adaptive backtracking can be obtained by importing a modified or tuned GHI and DHI, rather than importing the external GPOA. The GHI and DHI should be tuned so that once it is transposed by the modeling software, the final GPOA used for the simulation actually matches or substantially matches that of a tracker employing a terrain-adaptive backtracking strategy, even though the modeling program may be using a gcr-based schedule. The modified GHI and DHI may be calculated externally by retro-transposing. FIG. 11 illustrates this process.

At 505, obtain an external GPOA of a solar array installed at a site. The external GPOA may be obtained by, e.g., physically measuring by sensors from an installed solar site using a terrain-adaptive backtracking strategy, or calculated from a measured GHI and DHI of the solar site and a terrain-adaptive backtracking schedule used by the trackers in the solar site.

At 510, obtain GCR based backtracking/rotation schedules. For example, the performance modeling program may provide and/or force the use of a standard gcr-based schedule of backtracking angles.

At 515, the schedule and the external GPOA retro-transposed. For example, with this external GPOA, one may use an external program utilizing the pvlib_gti_dirint function with Perez transposition and a standard gcr-based schedule of backtracking angles. This allows the external program to back-solve what GHI and DHI would be necessary to receive the same amount of plane of array insolation as a terrain-adaptive backtracking strategy on a gcr-based backtracking simulation. This tuned GHI and DHI, though it may not necessarily represent a physical and/or correct GHI or DHI of the relevant solar site, may be input into the performance modeling program at 520 so that it will solve for a final GPOA that matches or substantially matches the external GPOA of the site (solving for GPOA may include running a simulation on a 3D model of the array). This accurate or more accurate GPOA may be obtained even though the performance modeling software forces a gcr-based backtracking schedule different from the terrain-adaptive backtracking schedule used or desired to be used by the solar site. As a result, the performance of a site which uses terrain-adaptive backtracking schedule can be more accurately modeled in a program which does not allow such a schedule to be input, and/or which does not properly utilize a measured GPOA of the site. As a result at 525, the performance modeling program may use this more final accurate GPOA to properly determine an accurate or more accurate power of the solar site.

### Average Transposition

Depending on the size of the solar site and how many bays it contains, some performance modeling software do not have the capability to calculate GPOA for the amount of bays that are required to perform the bespoke method for the entire site. In this case, if it is possible to import into the modeling software POA calculated externally, then total POA of the site can be calculated by employing the modeling software to get POA of each bay individually, e.g., via the bespoke method. For example, the POA may be determined by a backtracking schedule and/or the bay's normal vector, the sun's normal vector, and the sun's irradiance. Once the POA for each bay is calculated, a weighted average can be created with weights corresponding to the number of modules in a given bay. Alternatively, the POA for each bay can be obtained by other means than through modeling software, for example if the calculation is simple enough not to require modeling software. Regardless, the resulting total POA (e.g., GPOA) can be input into the modeling software. This process may be performed for every time step in a backtracking schedule.

For example if there was a three bay tracker at a solar site with one module, two modules and five modules in each bay respectively, then the POA for the tracker could be averaged as followed:

$$GPOA = 1 / 8 \times {POA}_{1} + 2 / 8 \times {POA}_{2} + 5 / 8 \times {POA}_{3}$$

Where POA₁ stands for bay 1 plane of array irradiance, POA₂ stands for bay 2 plane of array irradiance, POA₃ stands for bay 3 plane of array irradiance and GPOA indicates plant/site weighted average plane of array irradiance. In other words, POA of each bay is weighted based upon the ratio of its modules with respect to the total modules of the site, and the POA of the site is the sum of the weighted values of each bay. This method is called averaging at the plant level, since the plant in this case has one tracker. Using this methodology, an approximation can be made that is an intermediate between modeling the individual transposition of every bay and modeling the entire plant as flat. Different averaging strategies based off of this method can be employed to create further intermediaries. For example, if the modeling software in question allows the input of multiple plane of array irradiance time-series, then additional granularity can be added to the model by averaging transposition at the inverter, maximum power point tracker, tracker, or even string level. That is, the solar site may comprise multiple solar arrays, where each solar array has one or more modules; each solar array may be chosen as all of the modules connected to individual inverters, all the modules making up individual trackers or bays, or all the modules making up individual strings (where a bay may have more than one string, such as two strings physically adjacent to one another). Multiple “GPOAs” may be obtained for each solar array per the technique described above. These GPOAs may then be used in performance modeling to obtain the power generated by the solar site; for example, they may be input into a performance modeling software which models power generated by a solar site based on multiple plane of array inputs. Those looking for additional granularity without conducting the bespoke modeling method must assume that each step down in averaging size gives some respective increase in model accuracy. Averaged transposition may be created using pvlib (a tool for simulating the performance of photovoltaic energy systems). Averaging transposition may underestimate mismatch losses for the plant and may therefore cause modeled energy to be higher than actual energy.

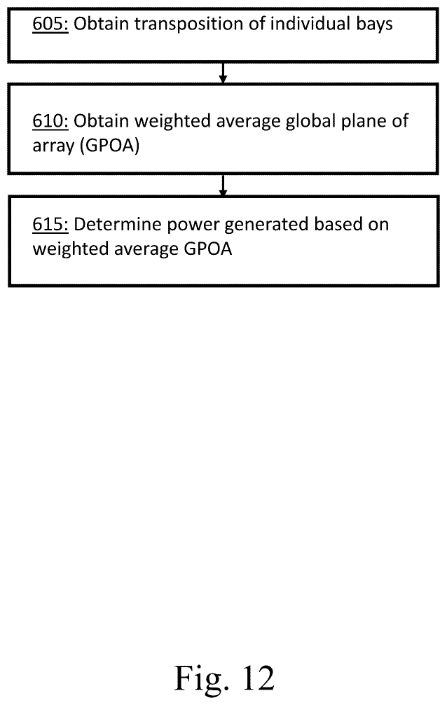

FIG. 12 illustrates an embodiment of the invention as described above. At 605 obtain transposition of individual bays (or other arbitrary array of modules). At 610 obtain the weighted average global plane of array as described above. At 615 determine power generated based on the weighted average GPOA, such as by plugging in the GPOA into a performance modeling program.

As described above, raycasting may be used to obtain an optimal backtracking schedule adapted to the solar sites installed on sloped land which prevents interrow shading from occurring between adjacent trackers. Obtaining this backtracking schedule by raycasting may help ensure that subsequent simplifications made for performance modeling will still result in as accurate a result as possible in relation to actual performance.

To start the raycasting process, elevation encoded location points of a particular solar array site need to be obtained. These points may describe a set of rectangular polygons. Each rectangular polygon encloses a contiguous set of solar modules sharing a common plane and having parallel normal vectors. For example, each rectangular polygon may enclose a bay. A tracker may be made up of multiple bays of solar modules. Each bay may be a grouping including one or more solar modules. Each bay may be disposed on a torque tube. Each bay may be between two bearings and/or foundations that allow angular change from bay to bay, whether that angular change is in the North-South or the East-West direction.

Sun angles are determined for the elevation encoded location points, then a schedule of true tracking angles are created for each tracker.

True tracking angles may be obtained by maximizing the irradiance collected through minimizing its incident angle on the solar module with the normal of the solar module. Single-axis trackers generally do not face directly towards the sun (e.g. the sun is south of the tracker) so the incident angle of the sun's beam is minimized by matching the solar module normal to the projection of the sun's position on the plane swept by the solar module normal over its entire range of motion. This matching solar module normal is the true tracking angle of the tracker, which changes throughout the day to create the schedule of angles.

By themselves, these true tracking angles may undesirably cause solar modules from neighboring trackers to shade each other, resulting in a large amount of power lost. Obtaining backtracking angles allows the trackers to avoid shading each other while sticking as closely as possible to the true tracking angles. These backtracking angles may be obtained by the raycasting process.

Using the schedule of true tracking angles, the sun's orientation with respect to each rectangular polygon—i.e., each bay of solar modules—is known. The schedule includes true tracking angles for each time step throughout the time period of interest, such as an entire day, an entire month, or entire year.

To start the raycasting process, elevation encoded location points of a particular solar array site need to be obtained. For example, the 3D geometry may be constructed using the tracker layer drawn in CAD, and the elevation encoded location points obtained from that construction. These points may describe a set of rectangular polygons. Each rectangular polygon encloses a contiguous set of solar modules sharing a common plane and having parallel normal vectors. For example, each set of the rectangular polygons may form a rectangular prism that encloses a bay. Alternatively, the elevation encoded location points may form an arbitrary polyhedron that is not necessarily a rectangular prism. A tracker may be made up of multiple bays of solar modules. Each bay may be a grouping including one or more solar modules. Each bay may be disposed on a torque tube. Each bay may be between two bearings and/or foundations that allow angular change from bay to bay, whether that angular change is in the North-South or the East-West direction. Each bay may extend beyond two bearings and/or foundations and be defined by a length of section of torque tube with a starting and ending point at different slope angles from the identified bay.

Sun angles are determined for the elevation encoded location points, then a schedule of true tracking angles are created for each tracker.

True tracking angles may be obtained by maximizing the irradiance collected through minimizing its incident angle on the solar module with the normal of the solar module. Single-axis trackers generally do not face directly towards the sun (e.g. the sun is south of the tracker) so the incident angle of the sun's beam is minimized by matching the solar module normal to the projection of the sun's position on the plane swept by the solar module normal over its entire range of motion. This matching solar module normal is the true tracking angle of the tracker, which changes throughout the day to create the schedule of angles.

By themselves, these true tracking angles may undesirably cause solar modules from neighboring trackers to shade each other when the sun is low in the sky in the morning and/or evening, resulting in a large amount of power lost. Obtaining backtracking angles allows the trackers to avoid shading each other while sticking as closely as possible to the true tracking angles. These backtracking angles may be obtained by the raycasting process.

Using the schedule of true tracking angles, the sun's orientation with respect to each rectangular polygon—i.e., each bay of solar modules—is known. The schedule includes true tracking angles for each time step throughout the time period of interest, such as an entire day, an entire month, or entire year.

To begin raycasting, light may be traced directly from the sun (e.g., computationally) as a light source to each bay. In the simplest incantation of a backwards ray tracing program such as those used in the movie and video game industries, rays are traced from a “camera”, through the pixels on a screen and into the scene and then finally towards a light source. Because a realistic image is not necessary to determine if a shadow is cast by the direct light from the sun, we can remove the camera and screen objects from our problem and trace the light from the light source (the sun) instead of towards it. First a particular starting tracker is chosen to define the direction of spawned light rays. The starting tracker may be the westernmost or easternmost tracker for an entire array of trackers on a site. The starting tracker may be on the opposite side of the sun or the furthest tracker from the sun in the array. In a first example, in the morning when the sun rises in the east, the westernmost tracker may be chosen as the starting tracker. Alternatively, the starting tracker does not have to be furthest from the sun, and may be chosen to be closest to the sun or neither closest nor furthest from the sun.

For this starting tracker, a set of light rays can be spawned for each bay in the tracker. To decrease total computation time, each ray can be defined by an origin corresponding to the corner of the bay and a direction corresponding to the unit vector coming from the direction of the sun. At a minimum two rays from the sun may be spawned for each bay directed to the upper two corners of that bay, e.g. the northern and southern corners furthest from the ground in a vertical direction when the solar module is tilted at any angle greater than 0 degrees (so that it is not parallel with the ground). With just these two rays spawned towards the upper corners, a reasonably accurate if not perfect assessment of whether shading occurs may be obtained, while saving on processing time compared to if many more rays were spawned. If neither of these two rays hits a bay behind the spawning bay, then it is less likely other rays spawned towards the starting tracker will intercept a bay behind the starting tracker. These two rays can thus indicate there will likely not be shading. If either of the two rays hit, then a ray in between them would also be hitting, so that shading can be determined without spawning more than two rays. In this optimization rays for the bottom two corners of the spawning bay do not need to be spawned. However, this is not a requirement, and any number of rays from two to millions of rays may be spawned for each bay. For example, more than 2 rays may be spawned for the upper edge of the bay 4 or less rays, such as 16 or less rays, such as 256 or less rays, such as 65536 or less rays. More rays may require more computational power and/or time but provide more certainty on whether or not shading is occurring. In the instance where more than two rays are spawned, the upper corners may still each have a ray spawned, with additional rays spawned on the upper edge of the bay in between the upper corners. However, this is not a requirement, and rays may be spawned at other edges of the bay, or within the body of the bay not on an edge.

The rays spawned may be spawned in the sense of taking a limit of a light ray approaching the corner of the spawning bay. In a physical sense, these rays may be partially blocked in real life depending on quantum theory, but in a classical sense they do not get blocked and glance the corners of the spawning bay to travel to the bay behind the spawning bay.

Once the rays are spawned towards the spawning bay, their trajectories as they relate to any bays behind the spawning bay are known. These bays may be on the tracker directly adjacent to the tracker of the spawning bay. They may also be on an opposite side of the sun with respect to the spawning bay. These bays are of interest because they may be shaded by the spawning bay. In other words, they are in the “field-of-view” of the spawning bay such that a light ray spawned towards the spawning bay may potentially intersect these other bays, which will be referred to as field-of-view bays. Intersection tests may be performed for these field-of-view bays. If the spawned rays intersect the field-of-view bay, the intersection test is positive. When the intersection test is positive, this means the spawning bay is shading the field-of-view bay at that time step.

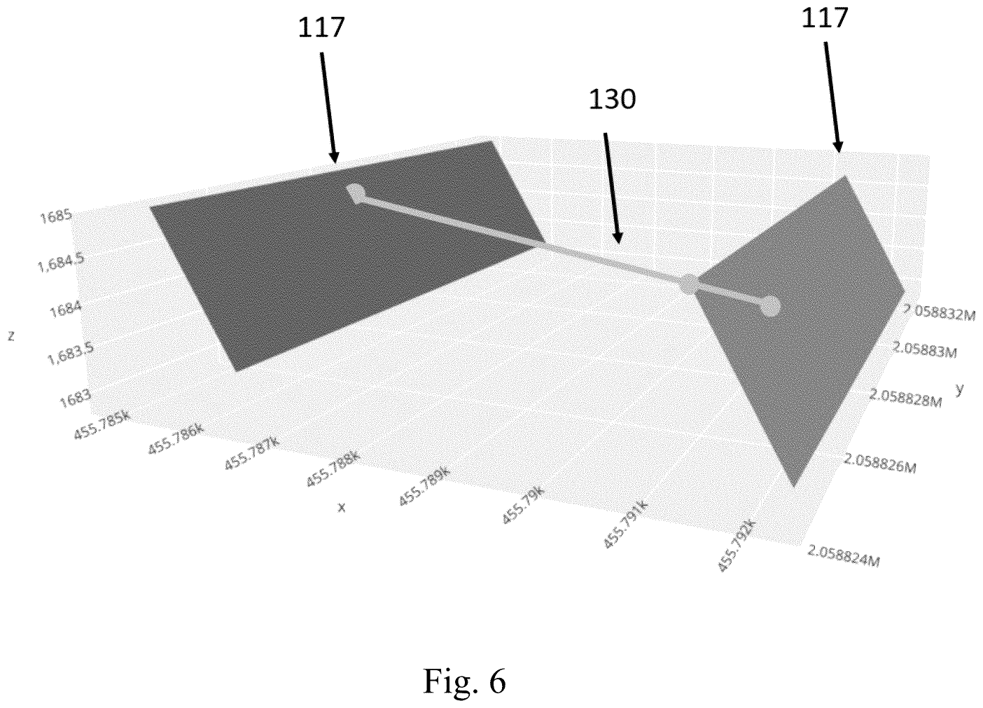

FIG. 6 depicts a ray 130 being spawned towards a first bay 117 (on the top of the page) and intersection tested with a second bay 117 (bottom of the page), both of which are angled away from the horizontal. The axes represent three dimensions of positions that the bays and ray inhabit. The sun from which the ray 130 is traced (not shown) is positioned towards the top of the page. The ray 130 is traced towards one of the upper corners of the first bay 117 and glances that corner (on the page, the direction of gravity is right). The ray 130 intersects with the second bay 117. This positive result for the intersection test means that at these angular orientations of the first and second bays 117, the first bay 117 shades the second bay 117.

Accordingly, the tracker of the spawning bay, the tracker of the shaded bay, or both trackers can be backtracked by a predetermined amount (e.g., 1-5 degrees, e.g., 1-3 degrees, such as 1 degree). Backtracking may occur after all spawning bays in a single tracker are tested, or after the first and/or each spawning bay in a single tracker is tested. Backtracking means to tilt the solar panels closer to flat or horizontal, e.g., closer to parallel with respect to an ungraded surface of the earth, or closer to parallel with a direction that is perpendicular to the earth's gravity. Both trackers may be backtracked the same amount or they may be backtracked different amounts. In embodiments of the invention, once both trackers are backtracked, raycasting as described above to test for any shading still occurring is done again until no shading occurs. Accordingly, new rays may be spawned on the backtracked spawning bay and an intersection test performed on the backtracked field-of-view bay(s), and if there is still shading, then the trackers for both bays are backtracked again a predetermined amount. This cycle of raycasting and backtracking may be repeated for as long as it takes until the spawning bay no longer shades any field-of-view bays.

Rays spawned by the spawning bay may be intersection tested with respect to more than any field-of-view bays depending on how many bays are in the field-of-view of the spawning bay. In certain sites depending on the terrain and other considerations, each bay in a tracker may not be perfectly aligned to bays in neighboring trackers, misalignment as referred to in the cross axial east to west direction. The northernmost and southernmost points of the spawning bay may bound the spawning bay's field of view (the field of view is given a limited definition here for the sake of optimization). Any neighboring bay behind the spawning bay with a northernmost or southernmost point between the spawning bay's field of view in the cross axial direction is considered a relevant field-of-view bay for intersection testing. For example, a first neighboring bay has its southernmost point in between the spawning bay's northernmost and southernmost points and a second neighboring bay has its northernmost point in between the spawning bay's northernmost and southernmost points. Even though the first neighboring bay's northernmost point is not in between the spawning bay's northernmost and southernmost points and the second neighboring bay's southernmost point is not between the spawning bay's northernmost and southernmost points, both the first and second neighboring bays are considered field-of-view bays that will be intersection tested.

The definition of the field-of-view may be expanded from that given above when accuracy is valued over computational speed and/or ease. For example, the spawning bay may have a field-of-view that not only includes any neighboring bay within the northernmost and southernmost point in the cross axial direction, but also includes any bays neighboring the neighboring bay in the axial direction (i.e., on the same tracker as the neighboring bay). Thus the intersection testing mentioned below could not only be done for the neighboring bay of the spawning trackers, but also those additional bays next to the neighboring bay. This field-of-view definition can be even further expanded to include more bays. For example, the field-of-view of the spawning bay can include not just the neighboring bay and those bays next to the neighboring bay, but may include all the bays in the tracker of the neighboring bay. For example, the field-of-view can include all the bays in the neighboring tracker, and all the bays adjacent to the neighboring tracker opposite the neighboring tracker from the tracker of the spawning bay. For example, the field-of-view can include all the bays in the solar site other than the bays in the tracker of the spawning bay, and other than the bays in trackers closer to the sun than the spawning tracker (e.g., closer as measured only in consideration of the east-west component). Each of these bays in the field-of-view may be intersection tested by the spawning bay as discussed below.

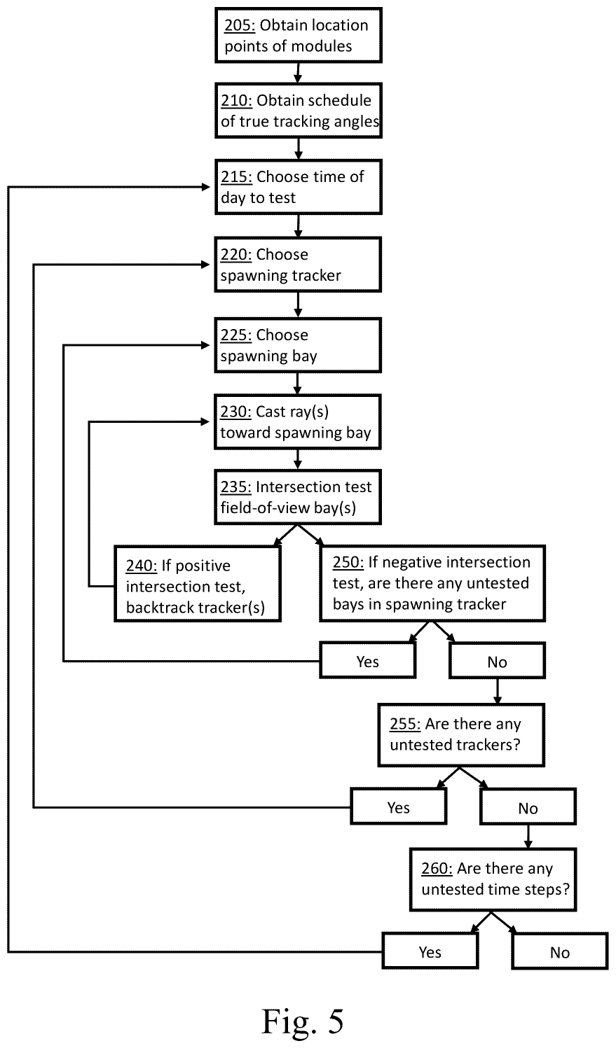

FIG. 5 depicts the method of raycasting in flow chart form. At 205, obtain the location points of modules. A solar module site which has either been physically installed at a physical site, or virtually built and modelled, is chosen for raycasting. The site may be an array of solar modules. The array may include trackers of solar modules, each of which include multiple bays of solar modules, where each bay may have one or more solar modules. Elevation encoded location points of the solar modules in the site are obtained. This may include getting location points for every bay of every tracker in the site, or only a portion of solar modules in the site. Each of these location points may describe a set of rectangular polygons. Each rectangular polygon encloses and/or represents a bay in the tracker.

At 210, obtain a schedule of true tracking angles. Once the elevation encoded locations points of the site are known, the schedule of true tracking angles may be obtained. The schedule may include the angle of some or every bay and/or tracker for each time step. The schedule may be in uniform time steps spaced out in equal intervals. The time steps may, for example, be in intervals of five minutes and span for at least an entire day, week, month, or year. Of course, the time steps and span may be any arbitrary time interval, and the time steps themselves may alternatively be nonuniform, for example to be more granular at more important times of the day compared to other times.

At 215, choose the time of day to test. The time is chosen from the schedule of true tracking angles. This choice may be made sequentially. For example, when starting testing, the chronologically earliest time may be chosen. Generally, the choice of the next time of day to test is the next untested chronological time step in the schedule. Of course, this is not necessary, and arbitrary times of day may be chosen for testing, depending on times of particular interest.

At 220, choose a spawning tracker (also referred to as a starting tracker in this description). The spawning tracker is defined as the tracker containing the spawning bay which will generate the rays for raycasting. When starting testing, the spawning tracker may be chosen from one extreme of the western and eastern side, such as the westernmost or easternmost tracker. Otherwise, the spawning tracker may be chosen from an untested tracker (e.g., untested in the current time step) directly adjacent to the last tested tracker. Alternatively, a non-tracker object, such as a tree, rock, or inverter, may be chosen as a substitute for the spawning tracker in at least parts of this method, to model the effects of a non-tracker object shading a neighboring bay as described below.

At 225, choose a spawning bay from the spawning tracker. When no other bay in the spawning tracker has yet been tested, the spawning bay may be chosen from the northernmost or southernmost bay. If any bays in the tracker have been tested, the next spawning bay may be chosen from an untested bay (e.g., untested in the current time step) directly adjacent to the last tested bay. For example, at the beginning of testing the spawning bay may be chosen as the northernmost bay, then after testing is done at the bay directly south of it may be chosen for testing.

At 230, perform raycasting for the chosen spawning bay. This may involve casting at least two rays from the sun towards the upper corners of the bay, as described above.

At 235, the spawned rays are used to intersection test with at least one neighboring bay to the spawning bay. The neighboring bay may be on a tracker directly adjacent to the spawning tracker in the cross-axial direction. The neighboring bay may be on the opposite side of the spawning tracker as the sun, in the cross axial direction. More than one of the neighboring bays are tested if at least some part of the neighboring bays are directly adjacent to the spawning bay. The next part of the method depends on the results of the intersection test. If the intersection test is positive, proceed to 240 and backtrack at least one of the involved trackers. For example, both the spawning tracker and the neighboring tracker which gave the positive intersection test may be backtracked. In embodiments of the invention, only one of the spawning tracker and the neighboring tracker may be backtracked. This backtracking may include modifying the schedule so that the resulting angle of the spawning and/or neighboring tracker replaces the true tracking or previous angle associated with the relevant time step. In any case, after backtracking, proceed to 230 once again, where rays are cast towards the (backtracked) spawning bay. Again at 235, the intersection test of these newly spawned rays are intersection tested with the (backtracked) neighboring tracker. This process may be repeated until the (iteratively backtracked) neighboring tracker gives a negative intersection test with the rays spawned towards the (iteratively backtracked) spawning bay.

Once the neighboring tracker gives a negative intersection test, 250 determines whether there are any untested bays in the spawning tracker, i.e., any bays for which rays have not been spawned for yet during this particular time step in the true tracking schedule. If there are, proceed to 225 where the next spawning bay is chosen. The spawning bay may be chosen in a sequential fashion as described above, or alternatively may be chosen arbitrarily from the remaining untested bays.

If there are no untested bays in the spawning tracker left, then 255 determines whether there are any untested trackers in the entire solar array site, i.e., whether there are any trackers for which none of its bays has been put through raycasting for this particular time step in the schedule. If there are, proceed again to 220 and choose the next spawning tracker as described above. If there are not, then proceed to 260 and determine whether there are any untested time steps in the schedule of true tracking angles, i.e., whether there are any time steps for which none of the bays in the site have been raycasted. If there are, choose the next time step in the schedule to test at 215, e.g., the chronologically next time step after the just tested time step. If there are not, then the method may complete.

Due to the fact that ray tracing is a time consuming process, a number of methods can be implemented so that the problem solves in a reasonable amount of time. These include reducing the amount of intersection tests required by choosing only reasonable objects that could possibly block direct irradiance, and having the raytracing processes run in parallel. For example, multiple instances of the method depicted in FIG. 5 may be run at once, for example on multiple processors or multiple computers. For example, the solar site may be divided into zones, and the method of FIG. 5 may be run in parallel for each zone.

In this way, utilizing raycasting on a solar site with a predetermined schedule of tracking angles may lead to a modified schedule of tracking angles that leads to increased power generation over the predetermined schedule. The methods used to increase power generation are particularly advantageous over previous methods because they may be used for a virtual site of solar trackers that has not been built yet, allowing a better determination of power generation of particular sites before a potentially costly commitment of installing solar trackers at the site.

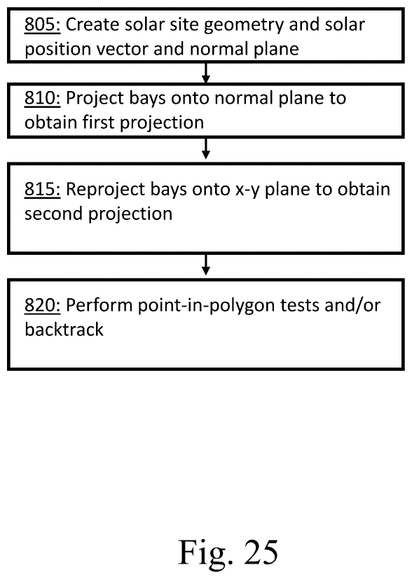

Instead or in addition to raycasting, a method of obtaining a backtracking schedule may involve projection of points onto a plane and point-in-polygon tests to find and reduce/remove shading. FIG. 25 depicts this process.

At 805, model geometry of a solar site by 3D points representing the trackers and bays forming the solar array and their initial rotational orientation at a given time. Each tracker, bay, and/or modules in the tracker/bay may be a polygon defined by four corner points (e.g., determined by the elevation encoded location points as described above with relation to raycasting). The trackers may be oriented as if they were, for example, installed on the rolling terrain of a physical site (e.g. with axial and/or cross-axial tilts), and be spaced apart and oriented in relation with each other the same way they would be at the physical site.

Model an x-y plane, and a solar position vector and a plane normal to the solar position vector. The solar position vector is determined by the position of the sun (i.e., azimuth and zenith angle) at the given time and a chosen point and can extend anywhere in between and/or through those two points. The chosen point may be a point at or near the solar array, and it may be chosen to be on the x-y plane. The plane normal to the solar position vector may be modeled anywhere on the solar position vector, from the chosen point to any arbitrary distance. As just one example, the chosen point and/or the normal plane may be at a distance from the solar array of anywhere from zero to twice the longest length of the solar array.

At 810, project the solar array onto the normal plane to form a first projection. This may establish where an overlap of modules in a solar array is happening from the viewpoint of the sun. The projection will flatten the 3D points representing the trackers and bays forming the solar array onto the normal plane, but the first projection may still have all nonzero x, y, and z coordinates at this stage.

At 815, re-project the first projection onto the x-y plane to form a second projection. The second projection may have its z coordinates set to zero for all points, simplifying calculations.

At 820, perform point-in-polygon tests using z-depth information from solar array layout. The z-depth information comes from the position of the sun, which indicates which direction the shadow is falling from. For example, if the trackers run substantially in the north-south direction, and the sun is west of due south, then the point-in-polygon tests would check starting from the westernmost tracker to see if it is shading its eastern neighbor, going from west to east along the trackers sequentially to check for shading in each tracker pair. If the sun is in the east the checking would be from east to west starting at the easternmost tracker and its western neighbor.

The point-in-polygon tests may be performed at the corners of tracker/bay polygons, or any other points of the polygons, such as any point between the corners on the edge of a polygon. A positive point in polygon test indicates that the bay that is in the corner of its neighbor's polygon is causing interrow shading of that neighbor.

If any shading is found, backtracking may be performed on one or more trackers/bays of the unprojected 3D solar array. That is, the unprojected polygons representing the trackers/bays, may be rotated so that at least one of them in the array is at a new angle. The backtracking may occur in degrees of 1 or less. For example, if it is found that a first tracker is shading a second tracker, then one or both of the first and second tracker may be backtracked, and so on for every tracker pair in the solar array where there is shading.

After all desired shade-casting and/or shaded trackers are backtracked to the desired amount, the process may loop back to 805 if desired, except the solar array is modelled as the backtracked solar array with a backtracked orientation instead of the initial orientation. The loop may repeat until all shading has been eliminated, one or more (e.g., all) trackers have reached zero degrees (a flat orientation), or other stopping criteria is reached. Other stopping criteria may be if a predetermined amount of backtracking by one or more trackers is reached before the solar array reaches zero shading, the process may stop looping and set the desired orientation at the given time in the backtracking schedule as the initial orientation of the solar array, before any backtracking occur. Or, it may set the desired orientation as one or more predetermined default orientations.

In any case, the desired orientation of the trackers at the given time has been determined, and the process can be repeated again for the next time step in the backtracking schedule. The time steps for a backtracking schedule may be any arbitrary interval, such as 5 minute time steps or less, such as 3 minutes or less, such as 1 minute or less. Once the backtracking schedule is obtained, it may be used to obtain or in conjunction with the other inputs described above, such as POA, to ultimately model the power generated by the solar array. For example, the backtracking schedule may be input into a program to obtain POA of one or more bays, such as an entire solar array of a site. This point-in-polygon method may be more computationally inexpensive than a raycasting method.

The process and methods described in this specification may be implemented by a hardware computer system. A computer system may include at least one of a processor, memory, non-volatile storage, and an interface. A typical computer system may include at least one or more of the following: a processor, memory, a general-purpose central processing unit (CPU), such as a microprocessor, or a special-purpose processor, such as a microcontroller.

The memory can include, by way of example but not limitation, random access memory (RAM), such as dynamic RAM (DRAM) and static RAM (SRAM). The memory can be local, remote, or distributed. The bus can also couple the processor to non-volatile storage. The non-volatile storage is often a magnetic floppy or hard disk, a magnetic-optical disk, an optical disk, a read-only memory (ROM), such as a CD-ROM, EPROM, or EEPROM, a magnetic or optical card, or another form of storage for large amounts of data. Some of this data is often written, by a direct memory access process, into memory during execution of software on the computer system. The non-volatile storage can be local, remote, or distributed. The non-volatile storage is optional because systems can be created with all applicable data available in memory.

Software may be stored in the non-volatile storage. Indeed, for large programs, it may not even be possible to store the entire program in the memory. Nevertheless, it should be understood that for software to run, if necessary, it is moved to a computer-readable location appropriate for processing, and for illustrative purposes, that location is referred to as the memory. Even when software is moved to the memory for execution, the processor may make use of hardware registers to store values associated with the software, and local cache that, ideally, serves to speed up execution. A software program may be assumed to be stored at an applicable known or convenient location (from non-volatile storage to hardware registers) when the software program is referred to as “implemented in a computer-readable storage medium.” A processor is considered to be “configured to execute a program” when at least one value associated with the program is stored in a register readable by the processor.

The computer systems can be compatible with or implemented as part of or through a cloud-based computing system. As used in this specification, a cloud-based computing system is a system that provides virtualized computing resources, software and/or information to client devices. The computing resources, software and/or information can be virtualized by maintaining centralized services and resources that the edge devices can access over a communication interface, such as a network. “Cloud” may be a marketing term and for the purposes of this specification can include any of the networks described herein. The cloud-based computing system can involve a subscription for services or use a utility pricing model. Users can access the protocols of the cloud-based computing system through a web browser or other container application located on their client device.

A computer system can be implemented as an engine, as part of an engine or through multiple engines. As used in this specification, an engine includes at least two components: 1) a dedicated or shared processor and 2) hardware, firmware, and/or software modules that are executed by the processor. Depending upon implementation-specific or other considerations, an engine can be centralized or its functionality distributed. An engine can include special purpose hardware, firmware, or software embodied in a computer-readable medium for execution by the processor. The processor may transform data into new data using implemented data structures and methods, such as is described with reference to the FIGS. in this specification.

The engines described herein, or the engines through which the systems and devices described herein can be implemented, can be cloud-based engines. A cloud-based engine may be an engine that can run applications and/or functionalities using a cloud-based computing system. All or portions of the applications and/or functionalities can be distributed across multiple computing devices, and need not be restricted to only one computing device. In some embodiments, the cloud-based engines can execute functionalities and/or modules that end users access through a web browser or container application without having the functionalities and/or modules installed locally on the end-users' computing devices.

Datastores may include repositories having any applicable organization of data, including tables, comma-separated values (CSV) files, traditional databases (e.g., SQL), or other applicable known or convenient organizational formats. Datastores can be implemented, for example, as software embodied in a physical computer-readable medium on a specific-purpose machine, in firmware, in hardware, in a combination thereof, or in an applicable known or convenient device or system. Datastore-associated components, such as database interfaces, can be considered “part of” a datastore, part of some other system component, or a combination thereof, though the physical location and other characteristics of datastore-associated components is not critical for an understanding of the techniques described herein.

Datastores can include data structures. A data structure may be associated with a particular way of storing and organizing data in a computer so that it can be used efficiently within a given context. Data structures may be based on the ability of a computer to fetch and store data at any place in its memory, specified by an address, a bit string that can be itself stored in memory and manipulated by the program. Thus, some data structures are based on computing the addresses of data items with arithmetic operations; while other data structures are based on storing addresses of data items within the structure itself. Many data structures use both principles, sometimes combined in non-trivial ways. The implementation of a data structure may entail writing a set of procedures that create and manipulate instances of that structure. The datastores can optionally be cloud-based datastores. A cloud-based datastore may be a datastore that is compatible with cloud-based computing systems and engines.

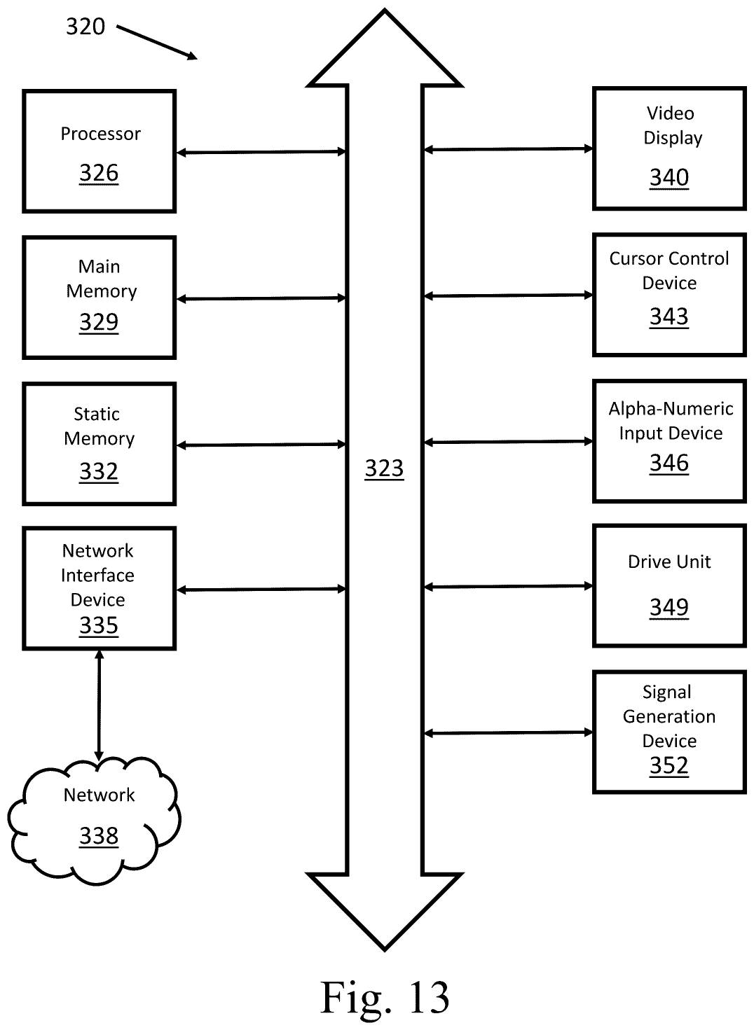

FIG. 13 is a block diagram of a machine in the example form of a computer system 320 within which instructions for causing the machine to perform any one or more of the methodologies discussed herein may be stored and/or executed. The machine may operate as a standalone device or may be connected (e.g., network) to other machines. In a networked deployment, the machine may operate in the capacity of a server or a client machine in a server-client network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 320 may include a processor 326 (e.g., a central processing unit (CPU), a graphics processing unit (GPU) or both), a main memory 329 and a static memory 332, which communicate with each other via a bus 323. The computer system 320 may further include a video display unit 340 (e.g., a liquid crystal display (LCD) or a cathode ray tube (CRT)). The computer system 320 also includes an alphanumeric input device 346 (e.g., a keyboard), a user interface (UI) navigation (or cursor control) device 343 (e.g., a mouse), a disk drive unit 349, a signal generation device 352 (e.g., a speaker) and a network interface device 335 connected to a network 338.

The disk drive unit 349 (e.g., a hard disk) may include a computer-readable medium on which is stored one or more sets of data structures and instructions (e.g., software and/or algorithms) embodying or utilized by any one or more of the methodologies or functions described herein. The instructions may also reside, completely or at least partially, within the main memory 329 and/or within the processor 326 during execution thereof by the computer system 320, the main memory 329 and the processor 326 also may constitute machine-readable media. The instructions may also reside, completely or at least partially, within the static memory 332.

The term “machine-readable medium” may include a single medium or multiple media (e.g., a centralized or distributed database, and/or associated caches and servers) that store the one or more instructions or data structures. The term “machine-readable medium” shall also be taken to include any tangible medium that is capable of storing, encoding or carrying instructions for execution by the machine and that cause the machine to perform any one or more of the methodologies of the present embodiments, or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including by way of example semiconductor memory devices (e.g., Erasable Programmable Read-Only Memory (EPROM), Electrically Erasable Programmable Read-Only Memory (EEPROM), and flash memory devices); magnetic disks such as internal hard disks and removable disks; magneto-optical disks; and compact disc-read-only memory (CD-ROM) and digital versatile disc (or digital video disc) read-only memory (DVD-ROM) disks. Machine-readable media may also include random access memory (RAM) (such as dynamic RAM (DRAM) and static RAM (SRAM)).

The instructions may further be transmitted or received over a communications network 338 using a transmission medium. The instructions may be transmitted using the network interface device 335 and any one of a number of well-known transfer protocols (e.g., HTTP). Examples of communication networks include a LAN, a WAN, the Internet, mobile telephone networks, POTS networks, and wireless data networks (e.g., WiFi and WiMax networks). The term “transmission medium” shall be taken to include any intangible medium capable of storing, encoding, or carrying instructions for execution by the machine, and includes digital or analog communications signals or other intangible media to facilitate communication of such software. The network interface device 335 may include one or more modems, network interface cards, wireless network interfaces or other interface devices, such as those used for coupling to Ethernet, token ring, or other types of networks.

Embodiments of the computer system may not require every element illustrated in FIG. 7 to be present, such that elements depicted in FIG. 7 may be optional. For example, an embodiment of a computer system used to implement embodiments of the invention may not include a signal generation device 352 or a cursor control device 343.

Some portions of the detailed description herein are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the below discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk, including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The algorithms presented herein are not inherently related to any particular computer or other apparatus. Various general purpose systems, messaging servers, or personal computers may be used with programs in accordance with the teachings herein, or it may prove convenient to construct a more specialized apparatus to perform the required method steps. The required structure for a variety of these systems appears in the description above. A variety of programming languages may be used to implement the teachings of the disclosure as described herein.

### Example Solar Site

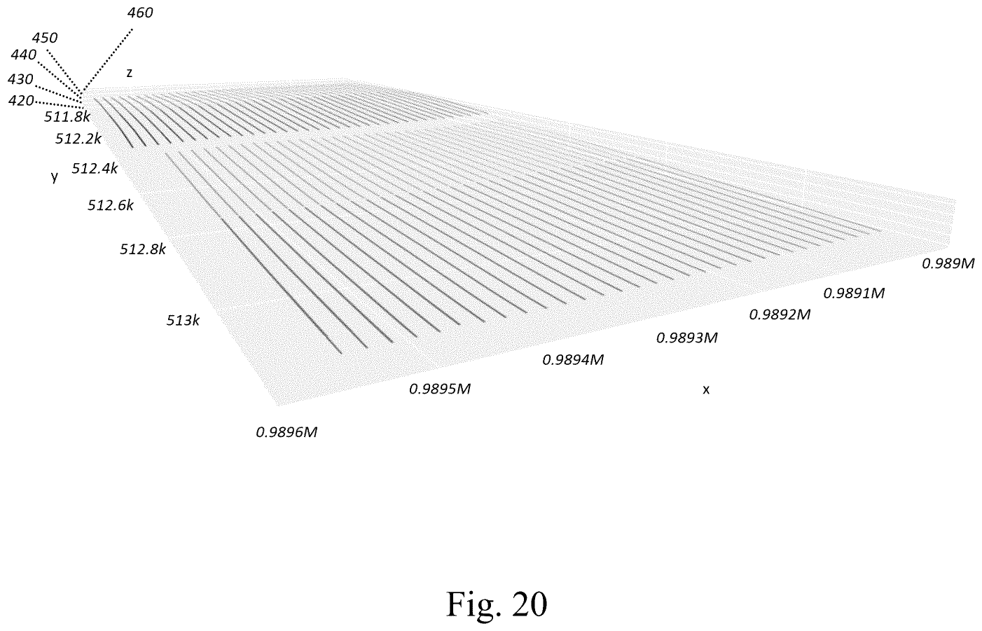

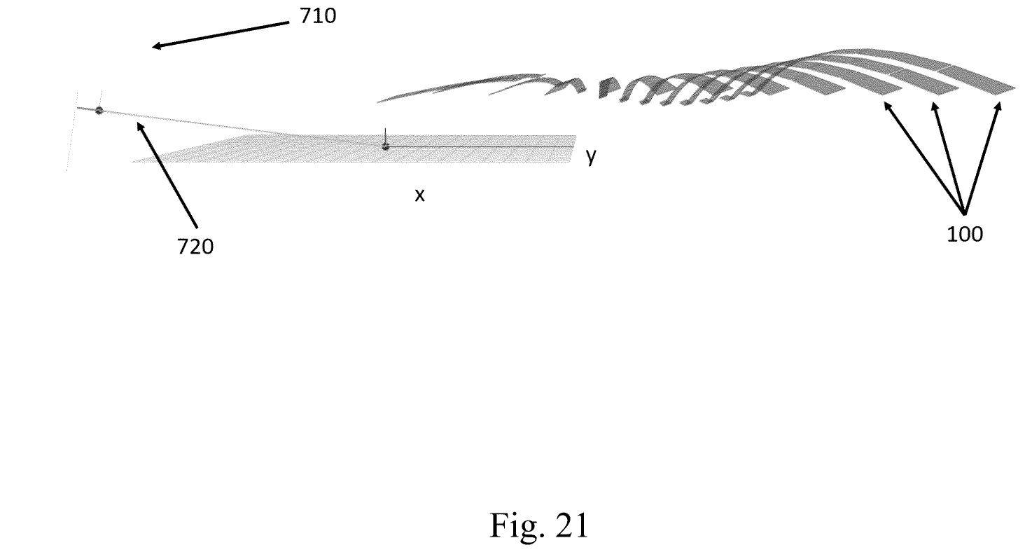

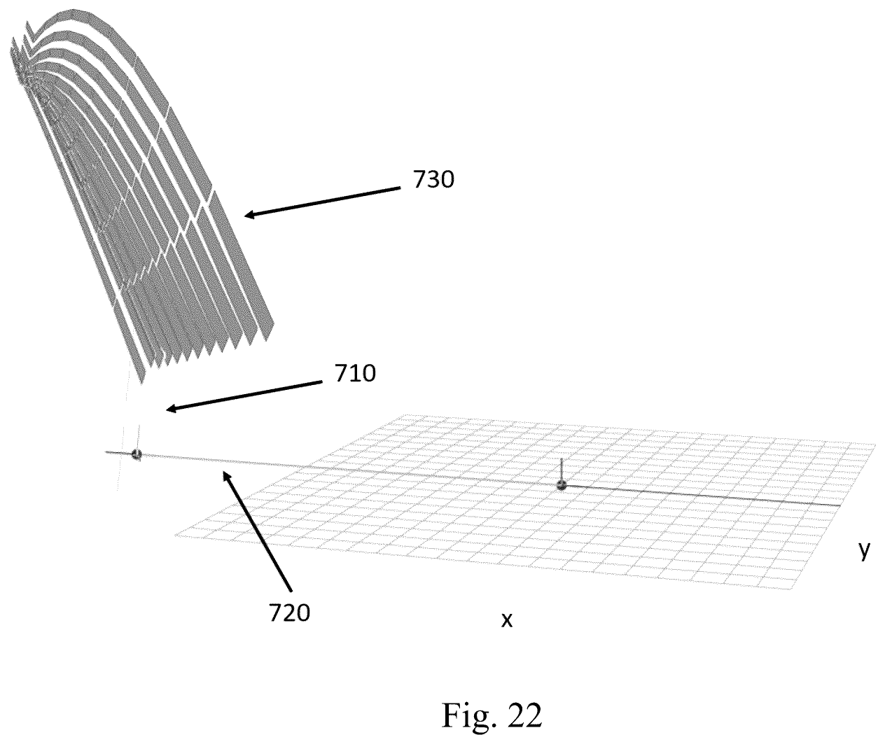

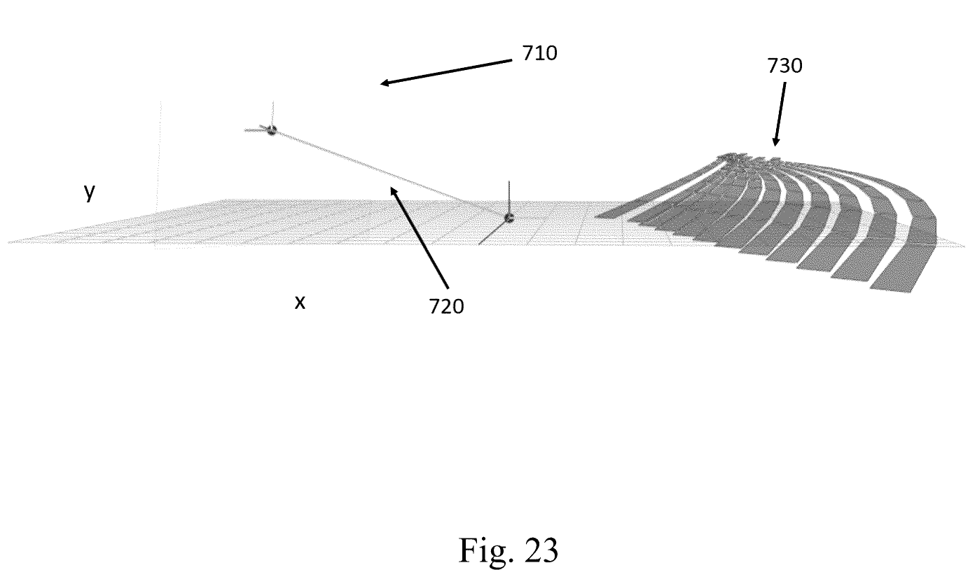

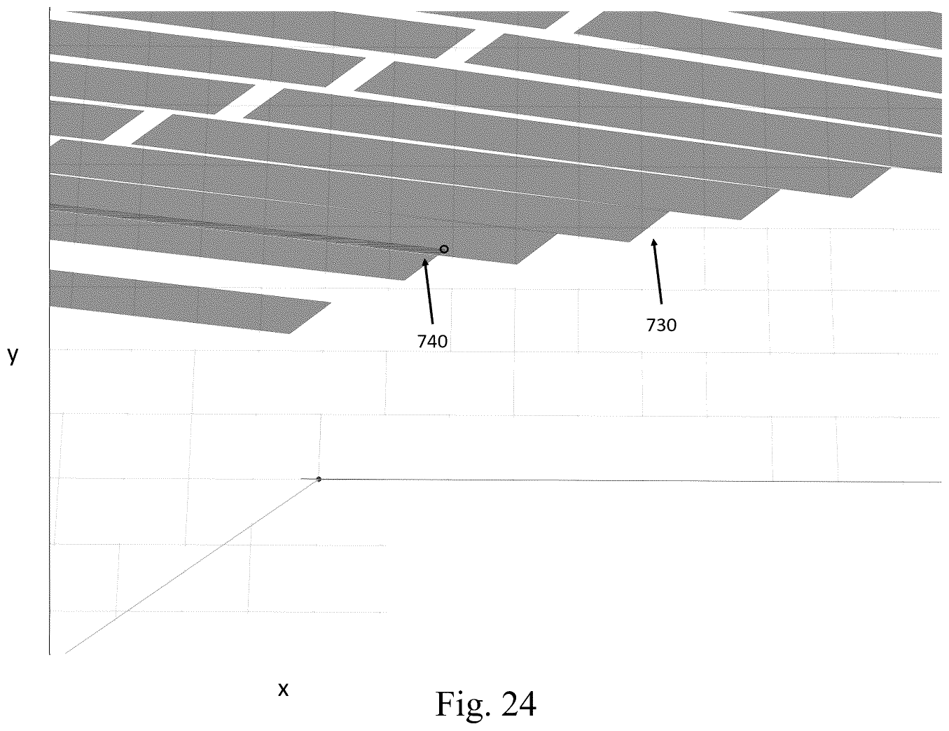

In order to generate models, one real world system of a solar array located in the United States was chosen, built with terrain-adaptive trackers with pile-to-pile bearings and angle changes. For every model, tracking schedules were generated using the site's actual physical geometry. For every model the Perez transposition model was used. Every model uses an hourly TMY weather dataset from the NSRDB's PSMv3 model with a diffuse fraction of 38%. A rigorous study conducted on the effects of 5 minute data compared to hourly data on terrain-following performance modeling has shown a near negligible effect of smaller time-steps on the overall model results. FIG. 20 shows a 3D Model of the solar site. Trackers are aligned north to south and are arranged in 4 distinct rows, with intervals of the x, y, and z axis marked by the italicized numbers.

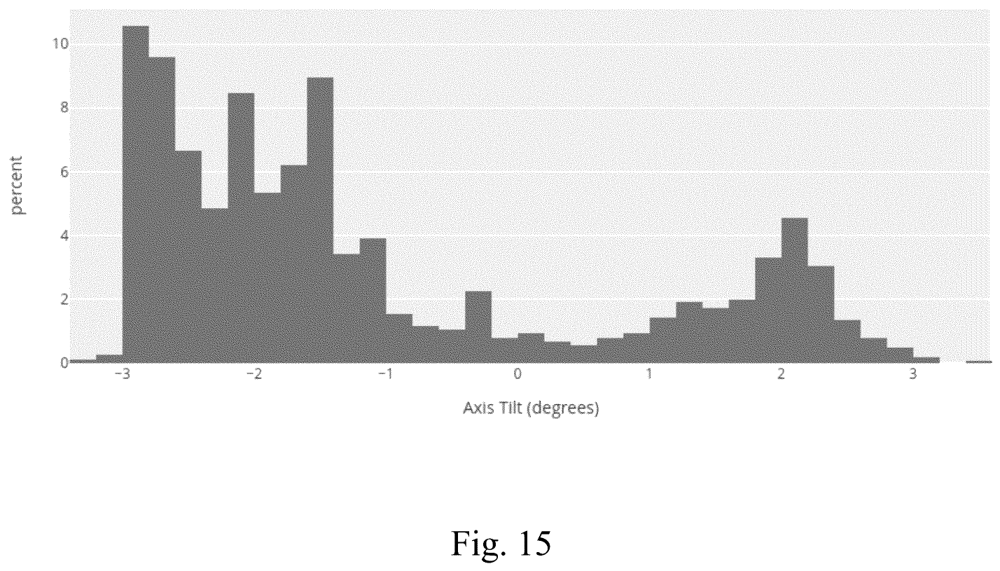

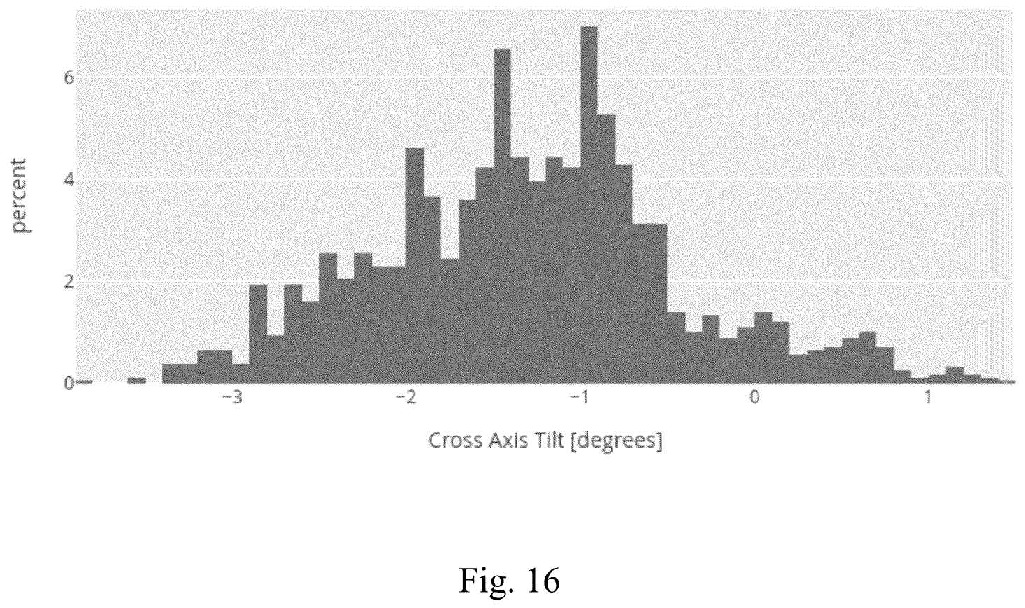

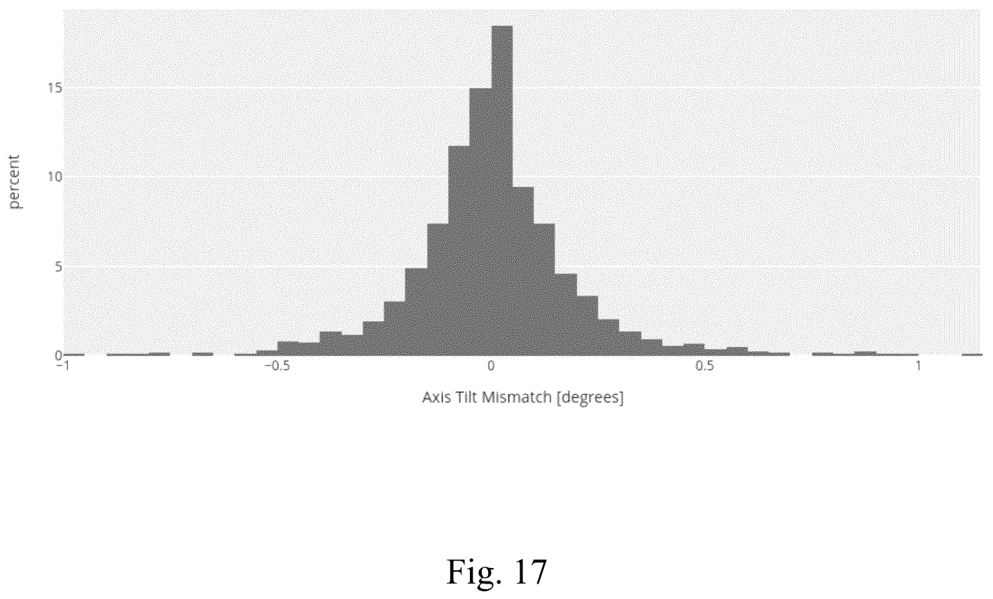

a.) Terrain: The project modeled in this paper is sited on a hill and is therefore sloped in all directions, but most of the site is dominated by a north eastern aspect. In table I statistics for torque-tube axis-tilt, cross-axis-tilt and axis-tilt mismatch are reported. Torque-tube axis-tilt is reported in the south to north direction with positive numbers indicating that the modules are inclined towards the southerly horizon. A histogram of torque-tube axis-tilts for the bays at the solar site can be found in FIG. 15. Cross-axis-tilt is reported in the west to east direction with positive numbers indicating that a given bay is lower in elevation than the bay directly east of it. A histogram of cross-axis-tilt can be found in FIG. 16. The negative peak of the distribution indicates that most of the system's trackers are lower in elevation than the tracker directly to its west. The process for calculating cross axis-tilt has difficulties for trackers with non-continuous torque-tubes, since a given bay may have a different torque tube axis angle than the bay directly east or west of it. Additionally, a bay may be offset to the north or south of a bay directly to its east or west. In either case, the center point of each bay was used for comparison, and no difference in torque tube axis-tilt is assumed. Differences in torque-tube axis angle from a given bay, compared to another bay on another tracker in the cross-axis direction are classified as axis-tilt mismatch. For example, if tracker 1 bay 1 has a torque-tube axis-tilt in the north/south direction of 1 degree and tracker 2 bay 1 directly east has a torque-tube axis-tilt in the north/south direction of 2 degrees, then the resulting axis-tilt mismatch would be −1 degrees. Only bays that are compared for cross axis-tilt are compared for axis-tilt mismatch. A histogram of axis-tilt mismatch can be found in FIG. 17. The peak centered around 0 degrees indicates that most trackers do not vary in north/south torque-tube axis-tilt from their cross-axis neighbors

TABLE I
Site Terrain Characteristics in Degrees

| Type | Min. | Mean | Max | St. Dev. |
|---|---|---|---|---|
| N/S Torque-Tube | −3.36 | −1.07 | 3.51 | 1.75 |
| Axis-Tilt | | | | |
| Cross-Axis Slope | −3.98 | −1.31 | 1.41 | 0.90 |
| Axis-Tilt | −0.96 | 0.00 | 1.13 | 0.20 |
| Mismatch | | | | |

b.) Backtracking: At the site, backtracking time-steps represent approximately 20% of all daylight tracking time-steps. This 20% of time-steps has a smaller impact on overall transposed insolation than true tracking time-steps relative to its proportion since backtracking is confined to the beginning and end of day when the sun is lower in the sky. Assuming a flat model, backtracking time-steps contribute approximately 16% of total plane of array irradiance. As ground coverage ratio increases, the amount of hours a system spends backtracking increases. As diffuse fraction increases, the less direct irradiance can be captured from irradiance components.

Table II shows the results of 9 transposition modeling methodologies used to model the system. Three major results have been bolded for emphasis. The first, entitled GCR Based, represents operating a site on terrain with a standard gcr-based backtracking algorithm. Average transposition represents the transposition expected when operating the site with a terrain-adaptive backtracking algorithm. Flat Model represents modeling the system as if it was built on flat ground. The table is organized from the smallest transposition gain to the most transposition gain in ascending order and a reference column has been provided so that each result can be easily matched to the underlying methodology described above in this specification. The global horizontal irradiance used in the weather file was included at the end of the table for reference.

TABLE II
Example Solar Site: Backtracking POA

| Method | Gain (%) | Insolation (kWh/m²) |
|---|---|---|
| GCR Based (0.36) | ~25 | ~2000 |
| Commissioning (0.42) | ~27 | ~2040 |
| Limit Ray Casting | 27.14 | 2034.64 |
| Retro-Transposition | 29.24 | 2068.23 |
| Avg. Transposition | 29.37 | 2070.35 |
| Avg. Rotation and Tilt | 29.47 | 2071.87 |
| Axis-Tilt Only | 30.90 | 2094.77 |
| Avg. Rotation Only | 30.93 | 2095.30 |
| Flat Model | 31.77 | 2108.79 |
| Global Horizontal | N/A | 1600.32 |

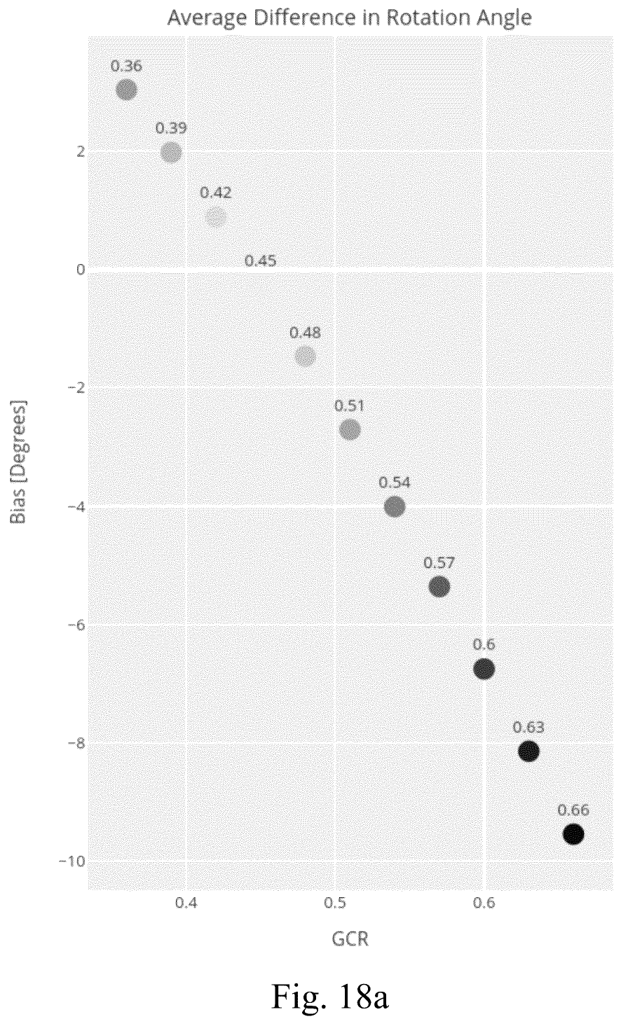

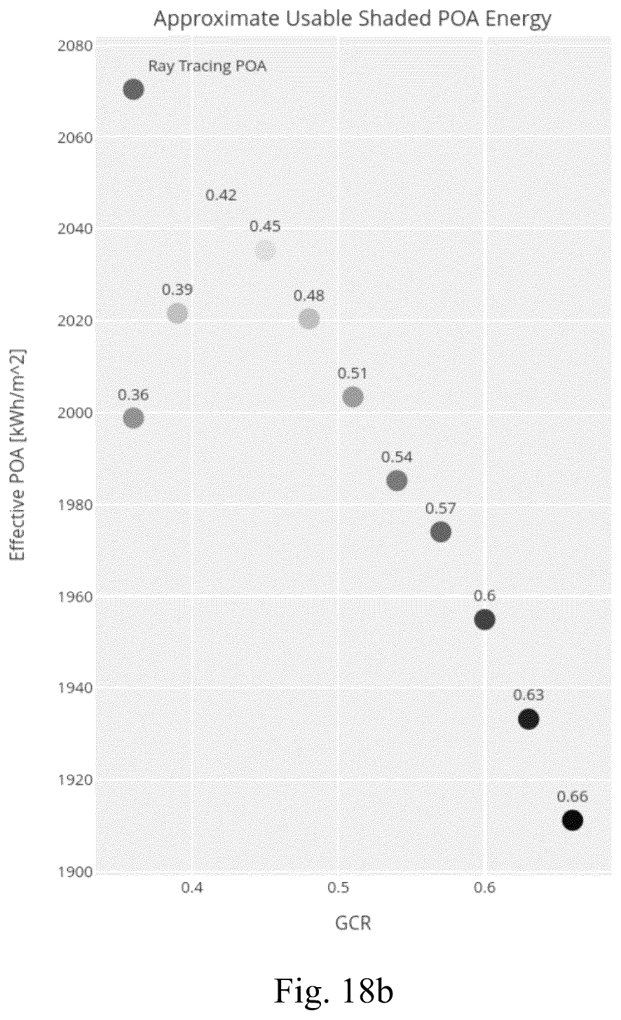

In table II, it can be seen that around 6 percent of usable transposition was lost due to terrain shading at the site when using the standard gcr-based backtracking strategy at 0.36 GCR compared to modeling the system as if it were flat. Usable transposition was calculated by setting a given bay's contribution to the plant's total transposed insolation to only the diffuse portion, during time-steps where the bay encountered shading. Even though the loss is an approximation, the magnitude of the loss is consistent with more rigorous models. Approximately 2 percent absolute, or 33 percent relative, lost transposition can be reclaimed by switching to a higher GCR of 0.42. Another 2.4 percent absolute, or 73 percent relative, lost transposition can be reclaimed by using the terrain-adaptive raycasting approach. These modeled results very closely match results from field-testing mentioned in prior work. FIGS. 18a and 18b compares both the rotation angles and the resulting plane of array insolation from a range of ground coverage ratio based backtracking strategies to ray-casting based rotation angles and plane of array insolation. FIG. 18a shows comparison of the mean bias in tracker rotation angle when comparing standard backtracking algorithms using different GCRs with Limit Ray Casting, while FIG. 18b shows comparison of usable unshaded POA using different GCRs compared to adaptive backtracking. Terrain-adaptive backtracking outperforms all ground coverage ratio based backtracking strategies at the site.

Averaging only the axis-tilt in the above table simulates a terrain which only has a northerly aspect of 1.07 degrees and no slope in the east/west direction. From this, one can assume that approximately 0.9% of the total loss in transposition can be attributed to the northerly aspect of the site. Approximately this amount of energy is un-recoverable by terrain-adaptive backtracking schedules at this site. On the other hand, averaging only the rotation angles while leaving axis-tilt as flat assumes a terrain which has no north/south slope, but does have varying slope in the east/west direction. From this, one can assume that the cross-axis slope and accompanying backtracking causes a similar decrease of 0.9%. One may notice that linearly adding the two components to 1.8% does not equal the 2.4% difference in transposition gain seen with the average transposition method. One possibility is that the additional losses are the cause of axis tilt mismatch, but due to the low amount of axis-tilt mismatch found at this site, one can assume that the contribution of this component to be small. It could be inferred that the difference is due to the non-linear nature of the Perez transposition model.

Another finding of note is that averaging the time series of tracker rotation angles as well as averaging the tracker axis-tilt before calculating transposition gives nearly the same amount of energy gain as computing transposition for every single bay. Averaging the rotation angles and tracker-axis tilts before calculating transposition removes the information requisite for calculating the subsequent electrical mismatch inherent to most utility-scale sites which do not have module level maximum power point tracking, but increases the speed of calculation. It is likely that using this method in practice will result in an overestimate of system performance due to underestimation of electrical mismatch losses.

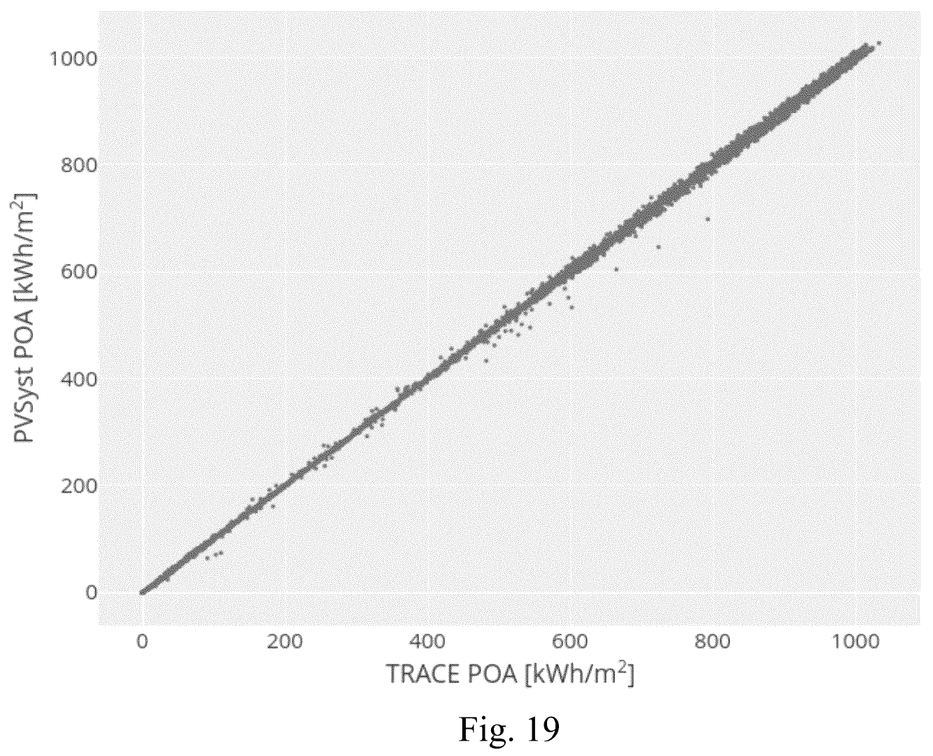

The method of retro-transposing the plane of array insolation generated with a terrain-adaptive backtracking strategy in order to back-calculate the necessary horizontal irradiance components needed to achieve the same plane of array insolation on a single-axis tracker employing a standard ground coverage ratio based backtracking strategy showed an R-squared correlation with the average transposition method of 0.9998. FIG. 19 shows a scatter-plot comparing plane of array insolation to plane of array insolation re-transposed in PVSyst.

c.) True Tracking:

TABLE III
True tracking

| Method | Gain (%) | Energy (kWh/m²) |
|---|---|---|
| Avg. Transposition | 36.06 | 2177.37 |
| Avg. Tracker Axis-Tilt | 36.09 | 2177.95 |
| Flat Model | 37.52 | 2200.72 |
| Global Horizontal | N/A | 1600.32 |

In the case of true tracking, averaging the tracker-axis-tilt resulted in a loss of 1.5%. It can be seen once again that averaging the relevant tracker angles successfully mimics the results of averaging transposition calculated for each bay. Though the losses incurred may seem smaller than in the backtracking case at first glance, additional near shading losses are expected, but not modeled here.

d.) Results: In this Example Solar Site, a selection of possible methodologies were tested in order to show both the ideal methodology and approximate methodologies which can be used to help bridge the gap between different modeling software. It has been demonstrated that using a closer spaced ground coverage ratio backtracking algorithm can recover around 33% of the losses incurred by terrain shading at the modeled site. Terrain-adaptive backtracking on the other hand can recover around 70% of the losses that may be incurred by terrain shading. Modeling terrain-adaptive backtracking as a standard ground coverage ratio based backtracking system on flat terrain may result in over-prediction of transposition gain around 2.4%. It has also been shown that averaging the rotation angle and torque-tube axis-tilt variables before calculating transposition may create a reasonable approximation of the more robust method which calculates a bespoke transposition result for every bay in the system, at least in terms of transposition, ignoring the rest of the performance modeling chain.

This disclosure is illustrative and not limiting. Further modifications will be apparent to one skilled in the art in light of this disclosure and are intended to fall within the scope of the appended claims.

1. A method for modeling the performance of a solar array, the method comprising:
determine a first plane of array (POA) of a first bay of the solar array, the first bay comprising a first quantity of one or more solar panels;
determine a second POA of a second bay of the solar array, the first bay comprising a second quantity of one or more solar panels;
determine a weighted global POA (GPOA) of the solar array based on the first POA, the second POA, the first quantity, the second quantity, and a third quantity of solar panels in the solar array; and
project power generated by the solar array based on the weighted GPOA.

2. The method of claim 1, wherein determining the weighted GPOA comprises weighing the first POA based on the first quantity and weighing the second POA based on the second quantity.

3. The method of claim 1, wherein the first bay comprises a different number of solar modules from the second bay.

4. The method of claim 1, wherein the first bay consists of a single solar module.

5. The method of claim 1, wherein the first bay comprises a plurality of modules.

6. The method of claim 1, wherein the first bay has a first normal vector and the second bay has a second normal vector, and the first and second normal vector are not parallel with each other.

7. The method of claim 1, further comprising:
obtaining a backtracking schedule of the solar array before determining the weighted GPOA.

8. The method of claim 7, wherein obtaining the backtracking schedule comprises performing a point-in-polygon test to determine an amount of shading in the solar array.

9. The method of claim 8, wherein obtaining the backtracking schedule comprises obtaining elevation encoded location points of the bays in the solar array and modeling the bays as polygons.

10. The method of claim 9, wherein obtaining the backtracking schedule comprises:
modeling a solar position vector based on a position of the sun at a given time and modeling a normal plane intersecting and normal to the solar position vector; and
modeling an x-y plane intersecting the solar position vector.

11. The method of claim 10, wherein the x-y plane is not parallel to the normal plane.

12. The method of claim 10, wherein obtaining the backtracking schedule comprises projecting the polygons onto the normal plane to obtain a first projection.

13. The method of claim 12, wherein obtaining the backtracking schedule comprises reprojecting the second projection onto the x-y plane.

14. The method of claim 13, wherein obtaining the backtracking schedule comprises backtracking the polygons to obtain a new orientation of the bays in the solar array.

15. The method of claim 1, wherein the backtracking comprises rotating at least one of the polygons by 1 degree or less.

16. The method of claim 14, wherein obtaining the backtracking schedule comprises, after backtracking the polygons, determining whether shading is occurring in the backtracked polygons.

17. The method of claim 7, wherein obtaining the backtracking schedule comprises raycasting to determine an amount of shading in the solar array.

18. The method of claim 1, wherein the first and second bay are comprised in a first tracker of the solar array, the solar array comprising a second tracker adjacent to the first tracker.

19. The method of claim 1, wherein the solar array comprises a third bay, further comprising: determining a third POA of the third bay, and
wherein determining the weighted GPOA is based additionally on the third POA.

20. A non-transitory computer-readable storage medium, storing computer-readable instructions operable to, when the instructions are executed on a processor, to:
determine a first plane of array (POA) of a first bay of the solar array, the first bay comprising a first quantity of one or more solar panels;
determine a second POA of a second bay of the solar array, the first bay comprising a second quantity of one or more solar panels;
determine a weighted global POA (GPOA) of the solar array based on the first POA, the second POA, the first quantity, the second quantity, and a third quantity of solar panels in the solar array; and
project power generated by the solar array based on the weighted GPOA.
